(19) United States
(12) Patent Application Publication
(10) Pub. No.: US 2021/0095374 A1
(43) Pub. Date: Apr. 1, 2021

(54) CVD Reactor Single Substrate Carrier and Rotating Tube for Stable Rotation

(71) Applicant: Veeco Instruments, Inc., Plainview, NY (US)

(72) Inventors: Sandeep Krishnan, Jersey City, NJ (US); Bojan Mitrovic, Somerset, NJ (US); Mandar Deshpande, Bridgewater, NJ (US); Alexander Gurary, Bridgewater, NJ (US); Aniruddha Bagchi, Belle Mead, NJ (US)

(73) Assignee: Veeco Instruments, Inc., Plainvew, NY (US)

(21) Appl. No.: 16/868,082

(22) Filed: May 6, 2020

Related U.S. Application Data
(60) Provisional application No. 62/827,789, filed on Apr. 1, 2019.

(51) Int. Cl. C23C 16/458; C30B 25/12

(52) U.S. Cl. CPC C23C 16/4584; H01L 21/0254; C30B 25/12

(57) ABSTRACT

A self-centering substrate carrier system for a chemical vapor deposition reactor includes a substrate carrier chosen to at least partially support a wafer for CVD processing and that comprises a beveled surface. A rotating tube comprising a beveled surface that matches the beveled surface of the substrate carrier, where a shape and dimensions of a cross section of the substrate carrier are chosen such that a center of mass of the substrate carrier is positioned a distance that is below a plane of contact defined by where a rim of substrate carrier contacts a rim of the rotating tube.

### CROSS REFERENCE TO RELATED APPLICATION

The present application is a non-provisional application of U.S. Provisional Patent Application No. 62/827,789, filed on Apr. 1, 2019, entitled “CVD Reactor Single Substrate Carrier and Rotating Tube for Stable Rotation”. The entire contents of U.S. Provisional Patent Application No. 62/827,789 are herein incorporated by reference.

The section headings used herein are for organizational purposes only and should not be construed as limiting the subject manner described in the present application in any way.

### INTRODUCTION

Many material processing systems include substrate carriers for supporting substrates during processing. The substrate is often a disc of crystalline material that is commonly called a wafer. One such type of material processing system is a vapor phase epitaxy (VPE) system. Vapor phase epitaxy is a type of chemical vapor deposition (CVD) which involves directing one or more gases containing chemical species onto a surface of a substrate so that the reactive species react and form a film on the surface of the substrate. For example, VPE can be used to grow compound semiconductor materials on substrates.

Materials are typically grown by injecting at least one precursor gas and, in many processes, at least a first and a second precursor gas into a process chamber containing the crystalline substrate. Compound semiconductors, such as III-V semiconductors, can be formed by growing various layers of semiconductor materials on a substrate using a hydride precursor gas and an organometallic precursor gas. Metalorganic vapor phase epitaxy (MOVPE) is a vapor deposition method that is commonly used to grow compound semiconductors using a surface reaction of metalorganics and hydrides containing the required chemical elements. For example, indium phosphide could be grown in a reactor on a substrate by introducing trimethylindium and phosphine.

Alternative names for MOVPE used in the art include organometallic vapor phase epitaxy (OMVPE), metalorganic chemical vapor deposition (MOCVD), and organometallic chemical vapor deposition (OMCVD). In these processes, the gases react with one another at the growth surface of a substrate, such as a sapphire, Si, GaAs, InP, InAs or GaP substrate, to form a III-V compound of the general formula In_{X}Ga_{Y}Al_{Z}N_{A}As_{B}P_{C}Sb_{D}, where X+Y+Z equals approximately one, A+B+C+D equals approximately one, and each of X, Y, Z, A, B, C, and D can be between zero and one. In various processes, the substrate can be a metal, semiconductor, or an insulating substrate. In some instances, bismuth may be used in place of some or all of the other Group III metals.

Compound semiconductors, such as III-V semiconductors, can also be formed by growing various layers of semiconductor materials on a substrate using a hydride or a halide precursor gas process. In one halide vapor phase epitaxy (HVPE) process, Group III nitrides (e.g., GaN, AlN) are formed by reacting hot gaseous metal chlorides (e.g., GaCl or AlCl) with ammonia gas (NH₃). The metal chlorides are generated by passing hot HCl gas over the hot Group III metals. One feature of HVPE is that it can have a very high growth rate, up to 100 μm per hour for some state-of-the-art processes. Another feature of HVPE is that it can be used to deposit relatively high quality films because films are grown in a carbon free environment and because the hot HCl gas provides a self-cleaning effect.

In these processes, the substrate is maintained at an elevated temperature within a reaction chamber. The precursor gases are typically mixed with inert carrier gases and are then directed into the reaction chamber. Typically, the gases are at a relatively low temperature when they are introduced into the reaction chamber. As the gases reach the hot substrate, their temperature, and hence their available energy for reaction, increases. Formation of the epitaxial layer occurs by final pyrolysis of the constituent chemicals at the substrate surface. Crystals are formed by a chemical reaction on the surface of the substrate and not by physical deposition processes. Consequently, VPE is a desirable growth technique for thermodynamically metastable alloys. Currently, VPE is commonly used for manufacturing laser diodes, solar cells, and light emitting diodes (LEDs) as well as power electronics.

### SUMMARY OF THE INVENTION

A self-centering substrate carrier system for a chemical vapor deposition reactor includes a substrate carrier chosen to at least partially support a wafer for CVD processing and that comprises a beveled surface. In some embodiments, the cross section of the substrate carrier is formed in a substantially rectangular shape overall. The substrate carrier can support an entire bottom surface of the wafer or the substrate carrier can support the wafer at a perimeter of the wafer, leaving a portion of both a top and a bottom surface of the wafer exposed.

A rotating tube comprising a beveled surface that matches the beveled surface of the substrate carrier, where a shape and dimensions of the cross section of the substrate carrier are chosen such that a center of mass of the substrate carrier is positioned a distance that is below a plane of contact defined by where a rim of substrate carrier contacts a rim of the rotating tube. The rotating tube can include vented sidewalls that assist in equalizing pressure in the regions above and below the substrate carrier.

In some embodiments, the beveled surface of the rotating tube and the beveled surface of the substrate carrier are parallel to each other. In one embodiment, the bevel surface of the substrate carrier and the beveled surface of the rotating tube are each at angle α relative to a rotation axis such that tan(α)>ƒ, where ƒ is a coefficient of friction between the substrate carrier and rotation tube.

In one embodiment, a shape and dimensions of the substrate carrier are chosen such that a center of mass of the substrate carrier is positioned a distance that is less than 0.5 mm from a plane of contact between the substrate carrier and rotating tube. In yet another embodiment, a shape and dimensions of the substrate carrier are chosen such that a center of mass of the substrate carrier is positioned at the plane of contact between the substrate carrier and rotating tube.

In some embodiments, a shape and dimensions of the substrate carrier are chosen such that a center of mass of the substrate carrier is positioned above the plane of contact between the substrate carrier and rotating tube. Also, in some embodiments, a shape and dimensions of the substrate carrier are chosen such that a center of mass of the substrate carrier is positioned below the plane of contact between the substrate carrier and rotating tube. Also, in some embodiments, a shape and dimensions of the substrate carrier are chosen such that a shape and dimensions of the substrate carrier minimize a destabilizing moment produced during rotation. Also, in some embodiments, a shape and dimensions of the substrate carrier is chosen so that there is a coincident alignment of a central axis of the substrate carrier and a rotation axis of the rotating tube during processing at a desired process temperature so that an axial-symmetrical temperature profile is established across the wafer. Also, in some embodiments, a shape and dimensions of the substrate carrier is chosen so that a rotation eccentricity of the wafer is substantially zero at the desired process temperature.

In some embodiments, the beveled surface of the substrate carrier and the beveled surface of the rotating tube are dimensioned to define a gap. The dimensions can be chosen so that a width of the gap approaches zero at the desired process temperature. The dimensions can also be chosen so that a width of the gap at room temperature provides space for thermal expansion of the substrate carrier relative to the rotating tube at processing temperatures. Also, a coefficient of thermal expansion of a material forming the substrate carrier and a coefficient of thermal expansion of a material forming the rotating tube can be chosen so that a width of the gap reduces during heating due to thermal expansion. Also, a coefficient of thermal expansion of a material forming the substrate carrier and a coefficient of thermal expansion of a material forming the rotating tube can be chosen so that the gap is maintained at processing temperatures.

### BRIEF DESCRIPTION OF THE DRAWINGS

The present teaching, in accordance with preferred and exemplary embodiments, together with further advantages thereof, is more particularly described in the following detailed description taken in conjunction with the accompanying drawings. The skilled person in the art will understand that the drawings, described below, are for illustration purposes only. The drawings are not necessarily to scale, emphasis instead generally being placed upon illustrating principles of the teaching. In the drawings, like reference characters generally refer to like features and structural elements throughout the various figures. The drawings are not intended to limit the scope of the Applicants' teaching in any way.

FIG. 1 illustrates one embodiment of a single wafer CVD reactor of the present teaching comprising a substrate carrier and rotating tube with heater assembly.

FIG. 2A illustrates a self-centering substrate carrier CVD system of the present teaching with a substrate carrier that has a beveled edge and a rim.

FIG. 2B illustrates a self-centering substrate carrier CVD system of the present teaching where the substrate carrier has been transferred into the process reactor (not shown) and positioned on the rotating tube at room temperature before the deposition process begins.

FIG. 2C illustrates a self-centering substrate carrier CVD system of the present teaching in the configuration described in connection with FIG. 2B but at process temperature.

FIG. 3A illustrates a self-centering substrate carrier system with a substrate carrier comprising a center of mass that is positioned a particular distance above a plane of contact between the substrate carrier and a rotation tube that supports the substrate carrier.

FIG. 3B illustrates a cross-section of the substantially non-rectangular self-centering substrate carrier that was described in connection with FIG. 3A in a reference rectangle.

FIG. 4A illustrates a substantially rectangular self-centering substrate carrier system according to the present teaching.

FIG. 4B illustrates the substantially rectangular self-centering substrate carrier of FIG. 4A in cross section in a reference rectangle.

FIG. 5A illustrates a cross section view of an embodiment of a rotating tube with venting sidewalls of the present teaching.

FIG. 5B illustrates an expanded view of the top region of the rotating tube described in connection with FIG. 5A.

FIG. 6A illustrates a cross section view of an embodiment of a rotating tube with a non-venting sidewall of the present teaching.

FIG. 6B illustrates an expanded view of the top region of the rotating tube of FIG. 6A.

FIG. 7A illustrates a perspective view of an embodiment of a non-venting rotating tube of the present teaching.

FIG. 7B illustrates a perspective view of an embodiment of a venting rotating tube of the present teaching.

FIG. 8 illustrates a partial view of a CVD reactor system that comprises an embodiment of a substrate carrier and rotating tube of the present teaching.

FIG. 9 is a top perspective view of a first embodiment of an ornamental design for a Rotating Tube for CVD Reactor;

FIG. 10 is a bottom perspective view of the first embodiment thereof;

FIG. 11 is a front view of the first embodiment thereof;

FIG. 12 is a rear view of the first embodiment thereof;

FIG. 13 is a left view of the first embodiment thereof;

FIG. 14 is a right view of the first embodiment thereof;

FIG. 15 is a top view of the first embodiment thereof;

FIG. 16 is a bottom view of the first embodiment thereof;

FIG. 17 is a cross section view taken along 17-17 in FIG. 15 of the first embodiment thereof; and

FIG. 18 is a partial scaled-up portion taken from FIG. 17 of the first embodiment.

FIG. 19 is a top perspective view of a second embodiment of an ornamental design for a Rotating Tube for CVD Reactor;

FIG. 20 is a bottom perspective view of the second embodiment thereof;

FIG. 21 is a front view of the second embodiment thereof;

FIG. 22 is a rear view of the second embodiment thereof;

FIG. 23 is a left view of the second embodiment thereof;

FIG. 24 is a right view of the second embodiment thereof;

FIG. 25 is a top view of the second embodiment thereof;

FIG. 26 is a bottom view of the second embodiment thereof;

FIG. 27 is a cross section view taken along 27-27 in FIG. 25 of the second embodiment thereof; and

FIG. 28 is a partial scaled up portion taken from FIG. 27 of the second embodiment.

FIG. 29 is a bottom view of a third embodiment of an ornamental design for a Rotating Tube for CVD Reactor;

FIG. 30 is a cross section view taken along 30-30 in FIG. 29 of the third embodiment thereof; and

FIG. 31 is a partial scaled up portion taken from FIG. 30 of the third embodiment thereof.

FIG. 32 is a top perspective view of an ornamental design for a Substrate Carrier;

FIG. 33 is a bottom perspective view thereof;

FIG. 34 is a top view thereof;

FIG. 35 is a bottom view thereof;

FIG. 36 is a left view thereof;

FIG. 37 is a right view thereof;

FIG. 38 is a front view thereof;

FIG. 39 is a rear view thereof;

FIG. 40 is a cross section view taken along 40-40 in FIG. 34 thereof; and

FIG. 41 is a partial scaled up portion taken from FIG. 40 of the first embodiment.

FIG. 42 is a top perspective view of a first embodiment of an ornamental design for a Multi-Filament Heater Assembly;

FIG. 43 is a bottom perspective view of the first embodiment thereof;

FIG. 44 is a front view of the first embodiment thereof;

FIG. 45 is a rear view of the first embodiment thereof;

FIG. 46 is a left view of the first embodiment thereof;

FIG. 47 is a right view of the first embodiment thereof;

FIG. 48 is a top view of the first embodiment thereof; and

FIG. 49 is a bottom view of the first embodiment thereof.

FIG. 50 is a top perspective view of a second embodiment of an ornamental design for a Multi-Filament Heater Assembly;

FIG. 51 is a bottom perspective view of the second embodiment thereof;

FIG. 52 is a front view of the second embodiment thereof;

FIG. 53 is a rear view of the second embodiment thereof;

FIG. 54 is a left view of the second embodiment thereof;

FIG. 55 is a right view of the second embodiment thereof;

FIG. 56 is a top view of the second embodiment thereof; and

FIG. 57 is a bottom view of the second embodiment thereof.

FIG. 58 is a top perspective view of a third embodiment of an ornamental design for a Multi-Filament Heater Assembly;

FIG. 59 is a bottom perspective view of the third embodiment thereof;

FIG. 60 is a front view of the third embodiment thereof;

FIG. 61 is a rear view of the third embodiment thereof;

FIG. 62 is a left view of the third embodiment thereof;

FIG. 63 is a right view of the third embodiment thereof;

FIG. 64 is a top view of the third embodiment thereof; and

FIG. 65 is a bottom view of the third embodiment thereof.

FIG. 66 is a top perspective view of a fourth embodiment of an ornamental design for a Multi-Filament Heater Assembly;

FIG. 67 is a bottom perspective view of the fourth embodiment thereof;

FIG. 68 is a front view of the fourth embodiment thereof;

FIG. 69 is a rear view of the fourth embodiment thereof;

FIG. 70 is a left view of the fourth embodiment thereof;

FIG. 71 is a right view of the fourth embodiment thereof;

FIG. 72 is a top view of the fourth embodiment thereof; and

FIG. 73 is a bottom view of the fourth embodiment thereof.

FIG. 74 is a top perspective view of a fifth embodiment of an ornamental design for a Multi-Filament Heater Assembly;

FIG. 75 is a bottom perspective view of the fifth embodiment thereof;

FIG. 76 is a front view of the fifth embodiment thereof;

FIG. 77 is a rear view of the fifth embodiment thereof;

FIG. 78 is a left view of the fifth embodiment thereof;

FIG. 79 is a right view of the fifth embodiment thereof;

FIG. 80 is a top view of the fifth embodiment thereof; and

FIG. 81 is a bottom view of the fifth embodiment thereof.

FIG. 82 is a top perspective view of a sixth embodiment of an ornamental design for a Multi-Filament Heater Assembly;

FIG. 83 is a bottom perspective view of the sixth embodiment thereof;

FIG. 84 is a front view of the sixth embodiment thereof;

FIG. 85 is a rear view of the sixth embodiment thereof;

FIG. 86 is a left view of the sixth embodiment thereof;

FIG. 87 is a right view of the sixth embodiment thereof;

FIG. 88 is a top view of the sixth embodiment thereof; and

FIG. 89 is a bottom view of the sixth embodiment thereof.

### DESCRIPTION OF VARIOUS EMBODIMENTS

The present teaching will now be described in more detail with reference to exemplary embodiments thereof as shown in the accompanying drawings. Reference in the specification to “one embodiment” or “an embodiment” means that a particular feature, structure, or characteristic, described in connection with the embodiment is included in at least one embodiment of the teaching. The appearances of the phrase “in one embodiment” in various places in the specification are not necessarily all referring to the same embodiment.

While the present teachings are described in conjunction with various embodiments and examples, it is not intended that the present teachings be limited to such embodiments. On the contrary, the present teachings encompass various alternatives, modifications, and equivalents, as will be appreciated by those of skill in the art. Those of ordinary skill in the art, having access to the teaching herein, will recognize additional implementations, modifications, and embodiments, as well as other fields of use, which are within the scope of the present disclosure as described herein.

It should be understood that the individual steps used in the methods of the present teachings may be performed in any order and/or simultaneously, as long as the teaching remains operable. Furthermore, it should be understood that the apparatus and methods of the present teachings can include any number, or all, of the described embodiments, as long as the teaching remains operable.

It is highly desirable to be able to deposit highly uniform films across an entire substrate by CVD deposition. However, the presence of any non-uniform temperature profiles across the substrate during deposition will lead to non-uniform deposited films. Methods and apparatus that improve uniformity of the thermal profile across the substrate over the duration of the deposition are needed to improve yield.

The present teaching relates to methods and apparatus for self-centering and stable rotation for a substrate carrier for CVD and other types of processing reactors which result in a more uniform temperature profile across the substrate during deposition. Aspects of the present teaching are described in connection with a single substrate carrier. However, one skilled in the art will appreciate that many aspects of the present teachings are not limited to a single substrate carrier.

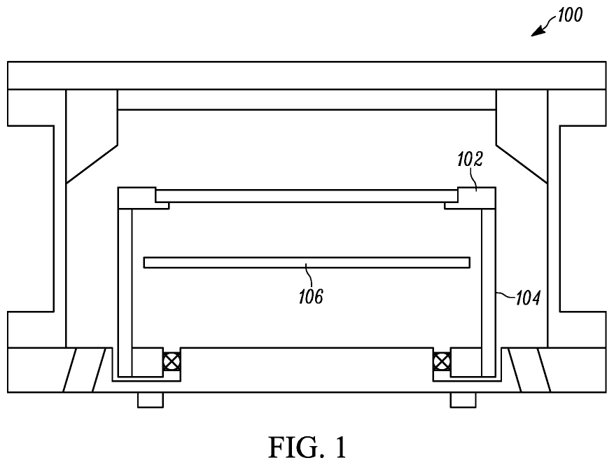

FIG. 1 illustrates one embodiment of a single wafer CVD reactor 100 of the present teaching comprising a substrate carrier 102 and rotating tube 104 with a multi-zone heater assembly 106. The rotating tube 104 may also be a jar, a rotating support or a cylindrical rotating support. The substrate carrier 102 is supported at the perimeter by the rotating tube 104. A multi-zone heating assembly 106 is positioned under the substrate carrier 102 inside the rotating tube 104. In this configuration, there is a diametral gap between the substrate carrier 102 and the rotating tube 104 that allows for carrier loading. The width of this diametral gap changes during heating because the substrate carrier 102 and the rotating tube 104 are designed with different coefficients of thermal expansion (CTE) resulting in different expansions as a function of temperature.

Substrate carriers and rotating tubes can be formed from a variety of materials such as, for example, silicon carbide (SiC), boron nitride (BN), boron carbide (BC), aluminum nitride (AlN), alumina (Al₂O₃), sapphire, silicon, gallium nitride, gallium arsenide, quartz, graphite, graphite coated with silicon carbide (SiC), other ceramic materials, and combinations thereof. In addition, these and other materials can have a refractory coating, for example, a carbide, nitride, or oxide refractory coating. Furthermore, the substrate carrier and rotating tubes can be formed from refractory metals, such as molybdenum, tungsten, and alloys thereof. Each of these materials, with or without coating, will have different coefficients of thermal expansion (CTE).

For example, the coefficient of thermal expansion (CTE) of SiC coated graphite, which is commonly used for the substrate carrier is −5.6×10⁻⁶° C.⁻¹. The coefficient of thermal expansion of quartz, which is commonly used as the rotating tube, is −5.5×10⁻⁷° C.⁻¹. The coefficient of thermal expansion of CVD SiC is −4.5×10⁻⁶° C.⁻¹. Given these coefficients of thermal expansion, an initial gap between the substrate carrier and the rotating tube at room temperature of about 0.5 mm reduces to about 0.05 mm at 1100° C.

A small gap at high operating temperatures is required to maintain the integrity of the quartz tube. Because of the changing gap width, known substrate carrier designs do not spin around the geometrical center of the substrate carrier as the temperature increases. This leads to a linear, or asymmetric, temperature distribution along the substrate carrier radius. Asymmetric temperature non-uniformities cause deposition uniformities which cannot be compensated for by multi-zone heating systems. Consequently, known substrate carriers for CVD reactors suffer from non-uniform asymmetric temperature profiles which result from the substrate carrier not rotating around its geometrical center.

One feature of the present teaching is that a substrate carrier according to the present teaching can provide coincidence of the substrate carrier central axis and the rotation axis of the rotating tube at process temperature. This coincidence reduces eccentricity of the circular rotation of the wafer in order to create an axially symmetric temperature profile that can be compensated for by properly using multi-zone heating elements.

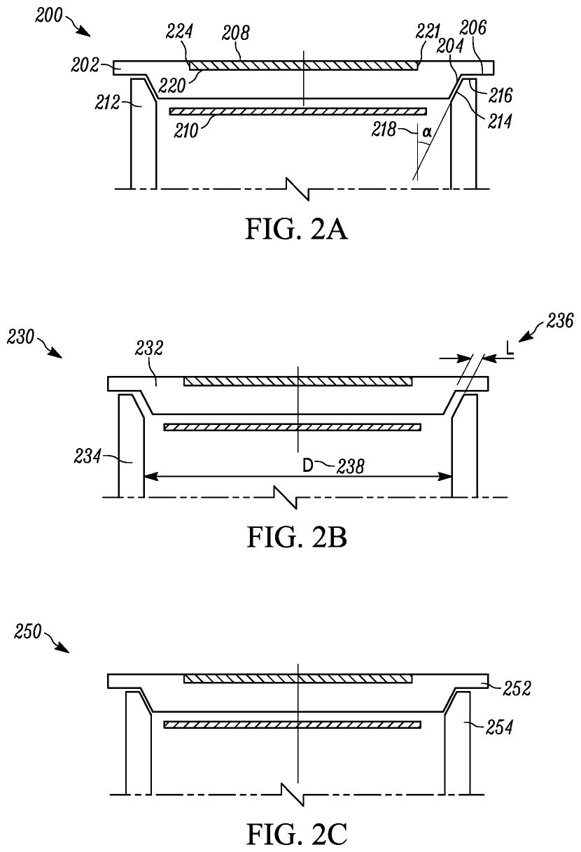

FIG. 2A illustrates a self-centering substrate carrier CVD system of the present teaching 200 with a substrate carrier 202 that has an edge 204 with a bevel geometry and a flat rim 206. The edge 204 of the substrate carrier 202 corresponds to a circular region at or near the outer perimeter of the substrate carrier. The edge 204 protrudes from the lower surface of the substrate carrier 202. A wafer 208, which is positioned in a pocket 220, is centered on the upper surface of the substrate carrier 202. A heating element 210 is located under the substrate carrier 202.

The wafer 208, which is positioned in pocket 220, the rim 206, and the heating element 210 are all positioned in parallel and stacked vertically in the CVD reactor as illustrated in FIG. 2A. The edge of wafer 208 contacts sidewall 224 of pocket 220 at a contact interface 221. The substrate carrier 202 is positioned on a rotating tube 212. The rotating tube 212 has an edge 214 with a beveled geometry and a flat rim 216. The substrate carrier edge 204 and the rotating tube edge 214 are proximate and parallel to each other when the substrate carrier 202 is positioned on the rotating tube 212. The bevel geometry on the edge 214 of the rotating tube 212 is formed at an angle α 218 with respect to the rotation axis of the rotating tube 212. Similarly, the bevel geometry on the edge 204 of the substrate carrier 202 is set at an angle α 218 with respect to the center-axis of the substrate carrier 202 that runs normal to the upper surface of the substrate carrier 202 that supports the wafer 208. In some embodiments, the angle α 218 relative to the rotation axis is chosen such that tan(α)>ƒ, where ƒ is the coefficient of friction between the substrate carrier 202 and the rotating tube 212 materials.

FIG. 2B illustrates a self-centering substrate carrier CVD system 230 of the present teaching where the substrate carrier 232 has been transferred into the process reactor (not shown) and positioned on the rotating tube 234 at room temperature before the deposition process begins. FIG. 2B illustrates a gap, with a width 236, L, and the rotating tube diameter 238, of width D. One feature of the substrate carrier of the present teaching is that the substrate carrier edge is dimensioned such that there is a gap with width 236, L, between the edge of the rotating tube 234 and the edge of the substrate carrier 232 at room temperature. In some embodiments, the dimensions of the substrate carrier 232 and the rotating tube 234 are selected such that a width 236, L, of the gap satisfies the following equation:

L<(CTE_{carrier}−CTE_{tube})*D*T,

where CTE_{carrier} is the coefficient of thermal expansion of the carrier 232, and CTE_{tube} is the coefficient of thermal expansion of the rotating tube 234, and T is the process temperature. The gap width 236, L, according to the above equation will decrease with increasing operating temperature, and just before the process temperature is realized, the width 236, L, of the gap will be substantially zero.

FIG. 2C illustrates a self-centering substrate carrier CVD system of the present teaching 250 in the configuration described in connection with FIG. 2B, but at process temperature. The close proximate distance between the beveled edges of the substrate carrier 252 and the rotating tube 254 result in a centering of the substrate carrier 252 on the rotating tube 254. Consequently, the substrate carrier's center axis and the axis of rotation are coincident. One skilled in the art will appreciate that numerous beveled geometries can be used to form the interface between the rotating tube 254 and the substrate carrier 252 that results in a centering of the substrate carrier 252 on the rotating tube 254.

One feature of the present teaching is that the geometry of the edge of the substrate carrier 252 and the geometry of the edge of the rotating tube 254 are configured to create a particular amount of eccentric or nearly eccentric rotation of the wafer during processing at process temperature. The amount of eccentric or nearly eccentric rotation of the wafer during processing is chosen to achieve a desired process temperature profile that results in a highly uniform film thickness profile.

One aspect of the present teaching is that edge geometries of the substrate carrier and the rotating tube according to the present teaching are chosen to provide a coincident alignment of a central axis of the substrate carrier and a rotation axis of the rotating tube during process at a desired process temperature. In some embodiments, the wafer or substrate supported by the substrate carrier can be positioned in a pocket in the surface of the substrate carrier, for example, like the pocket 220 described in connection with FIG. 2A. In other embodiments, the wafer is positioned directly on the surface of a substrate carrier not including any kind of pocket. This configuration is sometimes referred to as a pocketless substrate carrier. Pocketless substrate carriers typically include two or more bumpers or posts to hold the wafer into position.

One issue that arises in a substrate carrier that utilizes an edge with a shape that complements a shape of a rotating tube upon which the substrate carrier is situated during operation, where the substrate carrier is self-centered, is that applied forces can cause a tilt or a lifting off of the substrate carrier from the rotating tube. A variety of conditions cause a substrate carrier to be subject to various lateral forces during growth or operation of the CVD reactor system. These conditions arise, for example, from reactor/motor vibrations, centripetal forces due to manufacturing inconsistencies, wafer weight distribution, or movements that occur before the substrate carrier and rotating tube are fully interfaced at an operating temperature.

The interfacing of the substrate carrier edge and the rotating tube is a result of a gap between the substrate carrier edge and an edge of the rotating tube that diminishes at higher operational temperatures. The width of this gap changes during heating because the substrate carrier and the rotating tube have different coefficients of thermal expansion (CTE) resulting in different expansions as a function of temperature. A fully interfaced substrate carrier and rotating tube occurs when the gap is fully diminished to substantially zero.

The lateral forces on the substrate carrier can cause the substrate carrier to tilt and/or lift off the rotating tube. These tilting and/or lifting movements produce temperature non-uniformities across the surface of the substrate carrier as well as corresponding temperature non-uniformities across a surface of a wafer substrate that is placed on the substrate carriers. The temperature non-uniformities can result in corresponding growth non-uniformities for materials applied to the surface of the wafer substrate. These non-uniformities in growth lead to layer thickness variations across the surface of the substrate that are undesirable. Substrate carriers of the present teaching comprise a carrier cross section that can significantly reduce the undesirable tilt of the substrate carrier. Also, substrate carriers of the present teaching comprise a carrier cross section that can significantly reduce other undesirable motions of the substrate carrier such as wobble and/or vibration.

In some embodiments, the substrate carrier includes an edge geometry comprising a spacer. The spacer can be machined into the substrate carrier edge. The spacer in the substrate carrier edge geometry forces both a center axis of the substrate carrier and an axis of rotation of the rotating tube to align at a desired process temperature. See, for example, U.S. patent application Ser. No. 15/178,723, entitled “Self-Centering Wafer Carrier System for Chemical Vapor Deposition”, which is incorporate herein by reference and which is assigned to the assignee of the present application.

One feature of substrate carriers of present teaching is that they reduce stress that can cause non-uniform substrate carrier shape during operation. Substrate carriers of the present teaching also provide reduced stress in the coatings that are applied to the substrate carrier. Both of these stress conditions can lead to non-uniform growth of material on a wafer substrate. For example, some embodiments of the substrate carrier of the present teaching are fabricated using graphite material and are coated with a SiC coating. Wafer carriers with substantially non-rectangular cross sections that use SiC coated on graphite can exhibit out-of-plane deformation due to growth and CTE mismatch induced stresses. These stresses are especially significant during the substrate carrier manufacturing process. A more substantially rectangular cross section of substrate carrier will minimize this deformation.

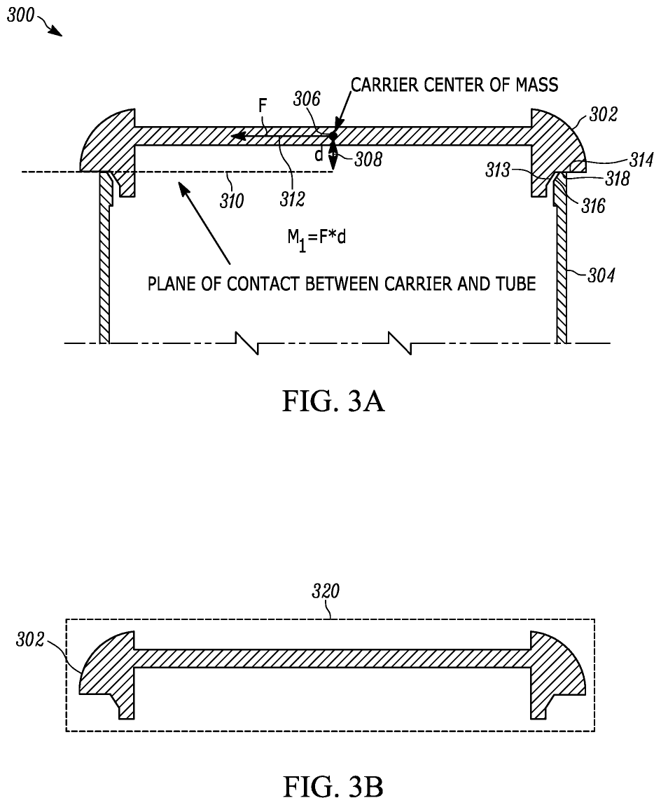

FIG. 3A illustrates a substantially non-rectangular self-centering substrate carrier system 300. The substantially non-rectangular self-centering substrate carrier system 300 includes a substrate carrier 302 and a rotating tube 304. The center of mass 306 of the substrate carrier 302 is positioned a particular distance 308, d, above a plane of contact 310 between the substrate carrier 302 and rotating tube 304. As understood by those skilled in the art, a center of mass of a particular element, which has a distribution of mass in space, is a unique point within or around the element for which the weighted relative position of the distributed mass sums to zero. The center of mass is the point for which an applied force 312, F, causes the element to move in the direction of the force with no rotation.

One aspect of the present teaching is that the shape and material of the substrate carrier 302 can be chosen to produce a center of mass at a particular location that reduces or otherwise manages the effect of the forces experienced by the substrate carrier 302 during operation. For example, the shape of the cross section of the substrate carrier 302 can be chosen to results in the center of mass 306 that is positioned substantially above the plane of contact 310 between the substrate carrier 302 and rotating tube 304. This is largely because the mass of the substrate carrier 302 substantially occupies a region that is positioned above the plane of contact 310 between the substrate carrier 302 and the rotating tube 304. A destabilizing moment is produced under the influence of any lateral force during rotation, which may be caused by vibrations or centripetal forces as described herein. For example, lateral force 312, F, causes a destabilizing moment M₁=F*d due to the distance 308, d, between the center of mass 306 of the substrate carrier 302 and the plane of contact 310 between the substrate carrier 302 and the rotating tube 304.

Similar to the embodiment described in connection with FIG. 2A, the substrate carrier 302 that has an edge 313 with a bevel geometry and a flat rim 314. The edge 313 protrudes from the lower surface of the substrate carrier 302. The substrate carrier 302 is positioned on the rotating tube 304. The rotating tube 304 has a corresponding edge 316 with a beveled geometry and a flat rim 318. The substrate carrier edge 312 and the rotating tube 304 corresponding edge 316 are configured to be proximate and parallel to each other when the substrate carrier 302 is positioned on the rotating tube 304. The plane of contact 310 between the substrate carrier 302 and rotating tube 304 is positioned where the rim 314 of substrate carrier 302 contacts the rim 318 of the rotating tube 304.

FIG. 3B illustrates a cross-section of the substantially non-rectangular self-centering substrate carrier 302 that was described in connection with FIG. 3A in a reference rectangle 320. The reference rectangle 320 encloses the perimeter of the substrate carrier 302. A comparison of the cross section of substrate carrier 302 and the reference rectangle 320 illustrate how the substrate carrier 302 exhibits a substantially non-rectangular shape. A substantial area of the reference rectangle 320 is not covered by the area of the substrate carrier 302 cross section.

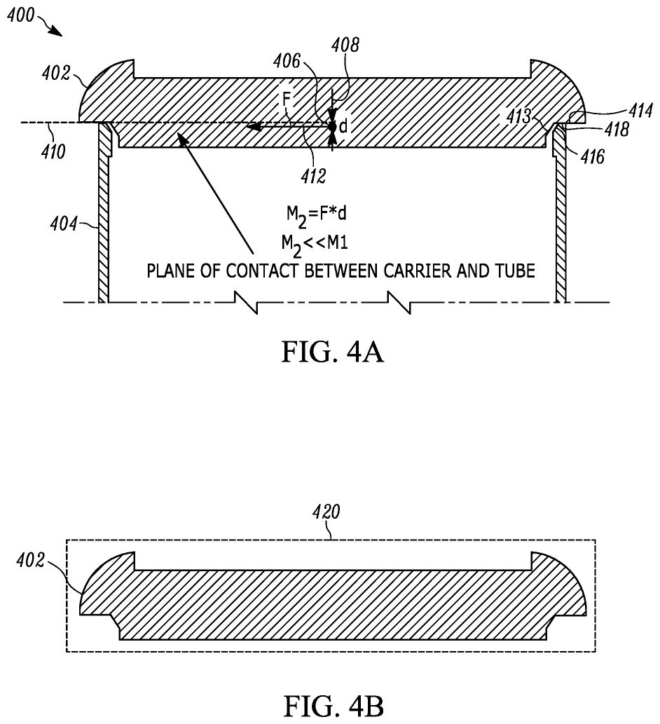

One feature of the present teaching is that a substantially rectangular substrate carrier cross section results in a center of mass that is positioned very close to a line touching the top of the rotating tube upon which the substrate carrier rests. FIG. 4A illustrates a substantially rectangular self-centering substrate carrier system 400 according to the present teaching. The substantially rectangular self-centering substrate carrier system 400 includes a substrate carrier 402 and a rotating tube 404. The substrate carrier 402 has a center of mass 406 that is positioned a distance 408, d, below a plane of contact 410 between the substrate carrier 402 and the rotating tube 404. The plane of contact 410 is at the line that touches the top of the rotating tube 404. The center of mass 406 is the point at which an applied force 412, F, causes the element to move in the direction of the force with no rotation.

The shape of the cross section of the substrate carrier 402 results in the center of mass 406 being positioned slightly below the plane of contact 410 between the substrate carrier 402 and rotating tube 404. This is because the mass of the substrate carrier 402 substantially occupies a region that is positioned above the plane of contact 410 between the substrate carrier 402 and the rotating tube 404. A destabilizing moment is produced under the influence of any lateral force during rotation, which may be caused by the vibrations or the centripetal forces described herein. In the configuration shown in FIG. 4A, however, the destabilizing moment is much smaller than the destabilizing moment of the substrate carrier 302 described in connection with FIG. 3A. For example, lateral force 412, F, causes a destabilizing moment, M₂=F*d, due to the distance 408, d, between the center of mass 406 of the substrate carrier 402 and the plane of contact 410 between the substrate carrier 402 and the rotating tube 404. Because the distance 408, d, is much smaller than the distance 308, d, in configuration shown in the embodiment of FIG. 3A, the destabilizing moment, M₂ is much smaller than the destabilizing moment, M₁.

It should be understood that it is the absolute value of the distance 308, 408, d, that determines the destabilizing moment, M₁, M₂. The sign of d is not a factor in determining the magnitude of the destabilizing moment, only its magnitude. Thus, it is highly desirable to have the distance 408, d, be as small as possible, but distance 408, d, can be above or below the plane of contact 410, depending on the particular configuration of the substrate carrier 402. In some embodiments, the substrate carrier of the present teaching is configured to have its center of mass and plane of contact in very close proximity, for example within less than 1 mm, in order to substantially reduce its destabilizing moments. In one specific embodiment of a 300 mm substrate carrier, the center of mass distance is ˜0.5 mm.

Similar to the self-centering substrate carrier 302 described in connection with FIG. 2A, the substrate carrier 402 has a beveled surface 413, which is an edge with a bevel geometry and a flat rim 414. The beveled surface 413 protrudes from the lower surface of the substrate carrier 402. The substrate carrier 402 is positioned on the rotating tube 404. The rotating tube 404 has a beveled surface 416, which also an edge with a beveled geometry and a flat rim 418. The beveled surface 416 of the rotating tube 404 is configured to be a matching or mating surface with the beveled surface 413 of the substrate carrier 402. In one embodiment, the beveled surface 413 of the substrate carrier 402 and the beveled surface 416 of the rotating tube 404 are matching edges that are proximate to and approximately parallel when the substrate carrier 402 is positioned on the rotating tube 404. The plane of contact 410 between the substrate carrier 402 and rotating tube 404 is positioned where the rim 414 of substrate carrier 402 contacts the rim 418 of the rotating tube 404.

One aspect of the present teaching is that a shape and a dimension of a cross section of the substrate carrier are such that a line through a center of mass of the substrate carrier is positioned close to a line contained in a plane of contact between the substrate carrier and the rotating tube to prevent undesired movement of the substrate carrier during operation.

FIG. 4B illustrates the substantially rectangular self-centering substrate carrier 402 of FIG. 4A in cross section in a reference rectangle 420. The reference rectangle 420 encloses the perimeter of the substrate carrier 402. A comparison of the cross section of substrate carrier 402 and the reference rectangle 420 illustrate how the substrate carrier 402 is formed in a substantially rectangular shape overall. As illustrated in FIG. 4B, a substantial area of the reference rectangle 420 is included in the area of the substrate carrier 402 cross section.

Modeling data has shown that a substrate carrier cross section that is substantially rectangular is also less prone to coating-stress-related deformation. Such a reduction in coating-stress-related deformation has the advantage that manufacturers can better hold carrier flatness tolerances and produce a less deformed carrier during the manufacturing process.

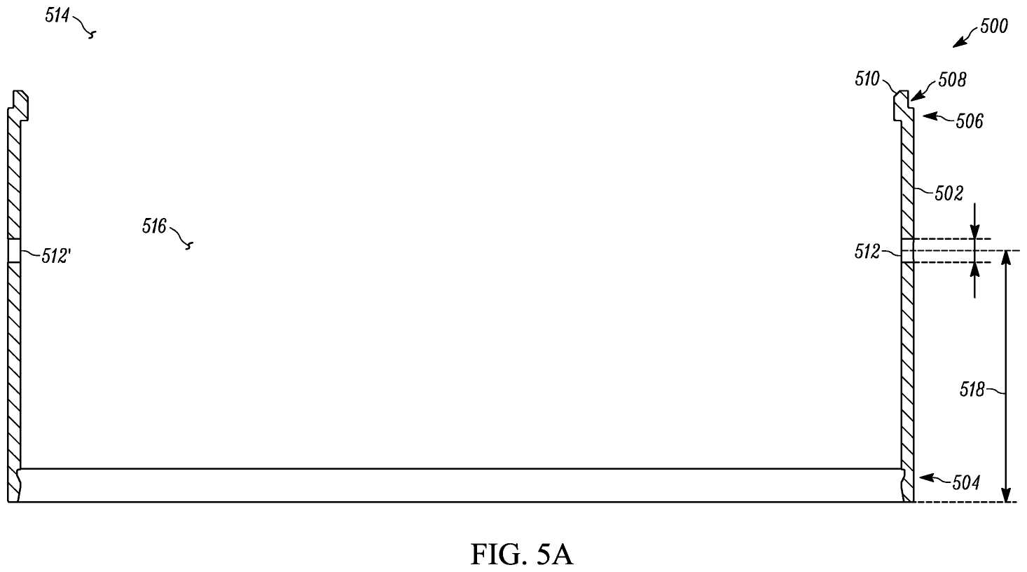

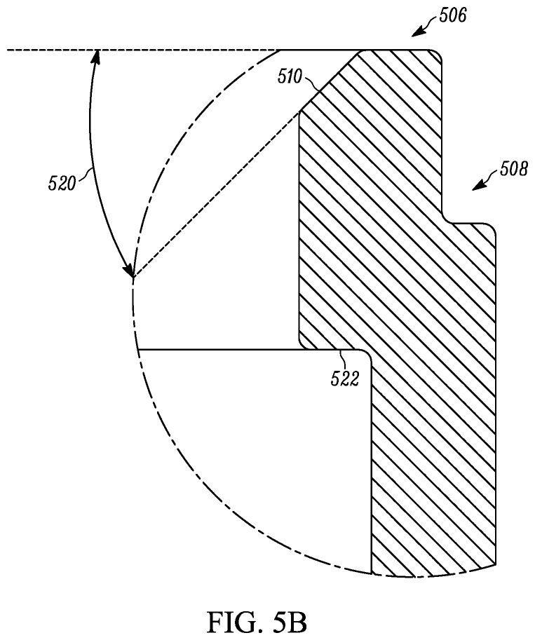

One feature of the rotating tube for supporting the self-centering substrate carrier of the present teaching is that it can also be configured to reduce mechanical stress. FIG. 5A illustrates a cross section view of an embodiment of a rotating tube 500 with venting sidewalls according to the present teaching. The cylindrical sidewall 502 is secured to the bottom region 504. The top region 506 is the region that supports the substrate carrier (not shown) and is offset from the center of the sidewall 502 in the bottom region 504. Thus, the offset top region 506 forms an outer notch 508 that is configured to improve airflow and to manage heat transfer. The inner edge 510 at the top is beveled as described herein to support a matching beveled edge of the substrate carrier (not shown).

A plurality of vent holes 512, 512′ are placed in the sidewall 502 and serve to passively equalize pressure in the regions above 514 and below 516 the position of the substrate carrier (not shown) and to prevent large differences of pressure during transients. These pressure differences can cause the substrate carrier to elevate during operation. In some embodiments, the vent holes 512, 512′ are situation to minimize stress. The optimum position of the vent holes 512, 512′ that result in the minimum stress points can be determined by simulation. In one particular embodiment, four vent holes 512, 512′ (two not shown) are positioned uniformly around the circumference of the sidewall 502 of the rotating tube. In some embodiments, the vent holes 512, 512′ are positioned with a center that is a distance 518 from the bottom of the rotating tube 500 that is closer to the top of the rotating tube 500 than to the bottom of the rotating tube 500. For example, in one particular embodiment, the distance from the top to the bottom of the rotating tube 500 is 6.55 inches, and the distance 518 from the bottom of the rotating tube 500 is 4.00 inches. Also in one particular embodiment, the diameter of the vent holes 512, 512′ is 0.38 inches. These dimensions present a relatively low stress in rotating tubes formed of, for example, fused quartz. Other dimensions can be used for rotating tubes formed of other materials.

FIG. 5B illustrates an expanded view of the top region 506 of the rotating tube 500 described in connection with FIG. 5A. In some embodiments, the notch 508 has a depth of 0.275 inches. The edge 510 has a bevel with an angle 520, which in some embodiments is about a 45-degree angle, as measured from the top of the rotating tube 500. A lower lip 522 is formed under the beveled edge 510.

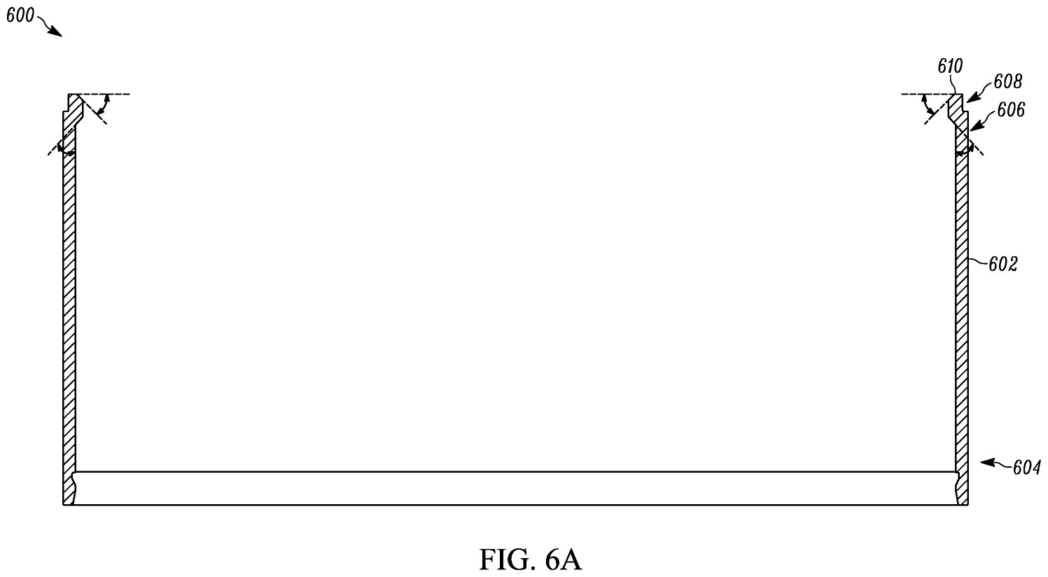

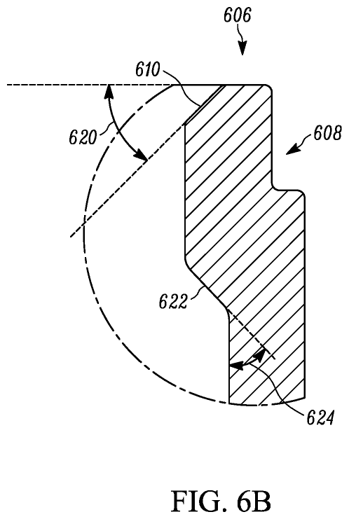

FIG. 6A illustrates a cross section view of an embodiment of a rotating tube 600 with a non-venting sidewall of the present teaching. The cylindrical sidewall 602 is secured at the bottom of the bottom region 604. The top region 606 is the region that supports the substrate carrier (not shown) and is offset from the center of the sidewall 602 in the bottom region 604. Thus, the offset top region 606 forms an outer notch 608 that is designed to improve airflow and manage heat transfer. The inner edge 610 at the top rotating tube 600 is beveled as described herein to support a matching beveled edge of a substrate carrier (not shown). In some embodiments, the sidewall 602 is formed of fused quartz, but numerous other materials can be used including a variety of dielectric materials.

FIG. 6B illustrates an expanded view of the top region 606 of the rotating tube 600 of FIG. 6A. In some specific embodiments, the notch 608 has a depth of about 0.275 inches. The edge 610 has a bevel with an angle 620, which in some embodiments is about a 45-degree angle, as measured from the top of the rotating tube 600. A lower lip 622 is formed under the beveled edge 610. In this embodiment, the lower lip 622 has a bevel that has an angle 624. This beveled edge helps to reduce mechanical stress and improve airflow. In some embodiments the angle 624 of the beveled lip 622 as measured from the edge of the sidewall is about 45 degrees.

In the embodiment of the rotating tube 600 described in connection with FIGS. 6A-B, there are no vent holes in the tube 600 making it more suitable for applications in which the vent holes could create stress and cause the rotating tube 600 to crack and to break. Referring to both FIGS. 5A-B and 6A-B, we note that the different embodiments of the top regions 506, 606 can be used both with vented and the non-vented sidewalls 502, 602.

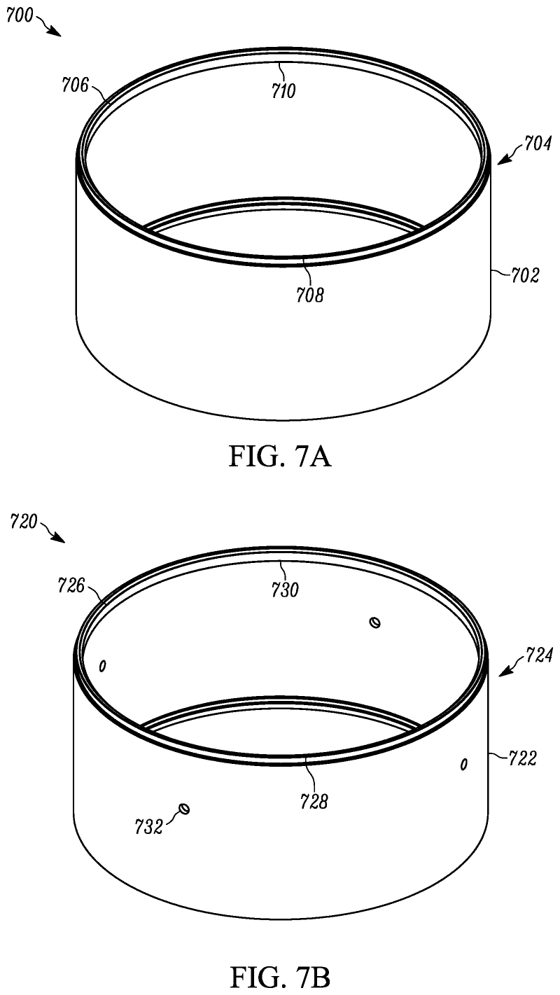

FIG. 7A illustrates a perspective view of an embodiment of a non-venting rotating tube 700 of the present teaching. The sidewall 702 of the cylindrically-shaped rotating tube 700 is shown. The top region 704 includes an inner beveled edge 706, an outer notch 708, and a lower lip 710.

FIG. 7B illustrates a perspective view of an embodiment of a venting rotating tube 720 of the present teaching. The sidewall 722 of the cylindrically-shaped rotating tube 720 is shown. The top region 724 includes an inner beveled edge 726, an outer notch 728, and a lower lip 730. The embodiment of FIG. 7B includes four vent holes 732. Other embodiments of a venting rotating tube of the present teaching can have at least one vent hole.

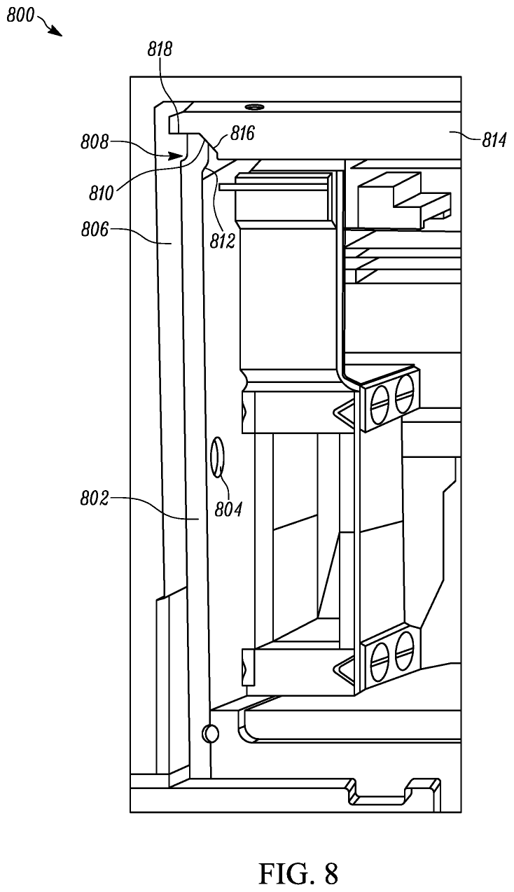

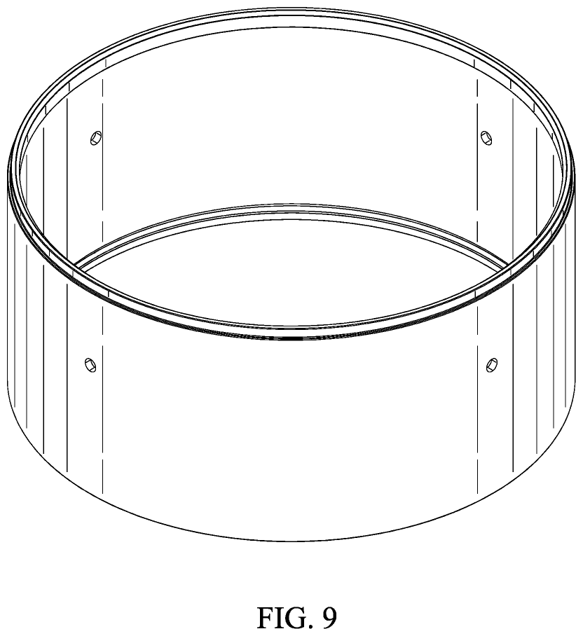

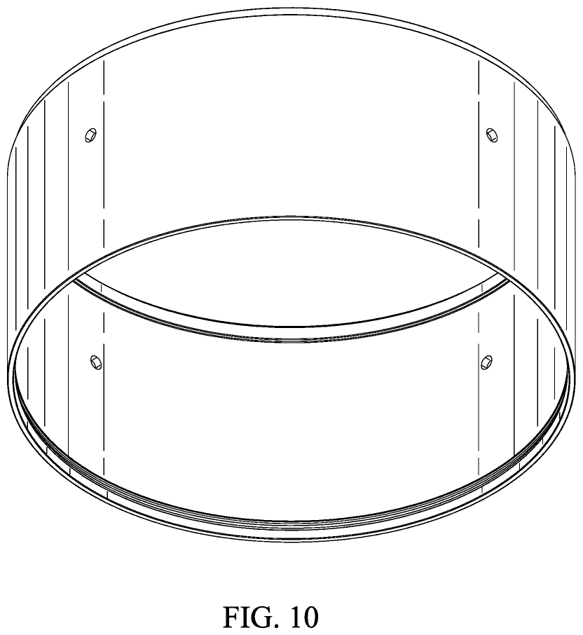

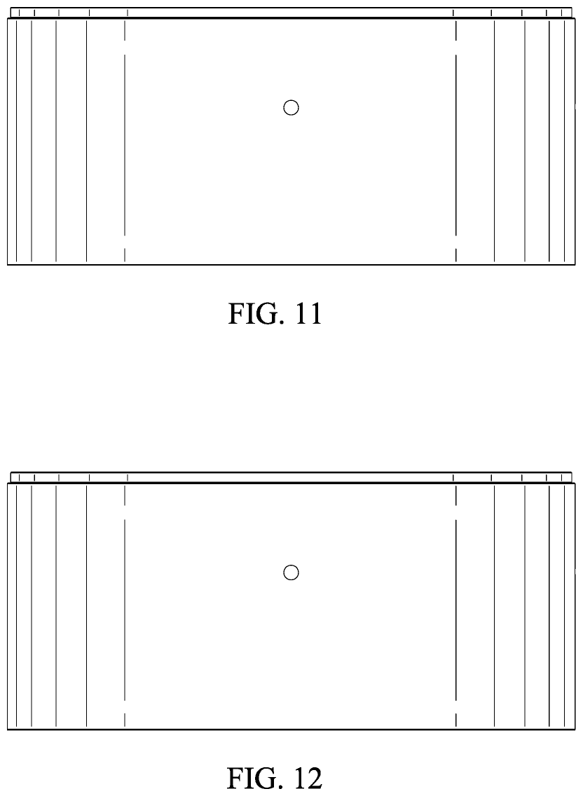

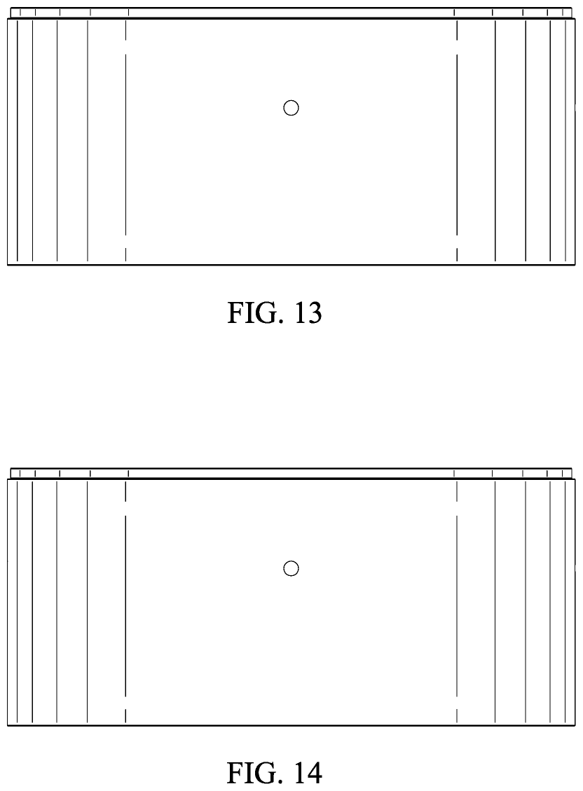

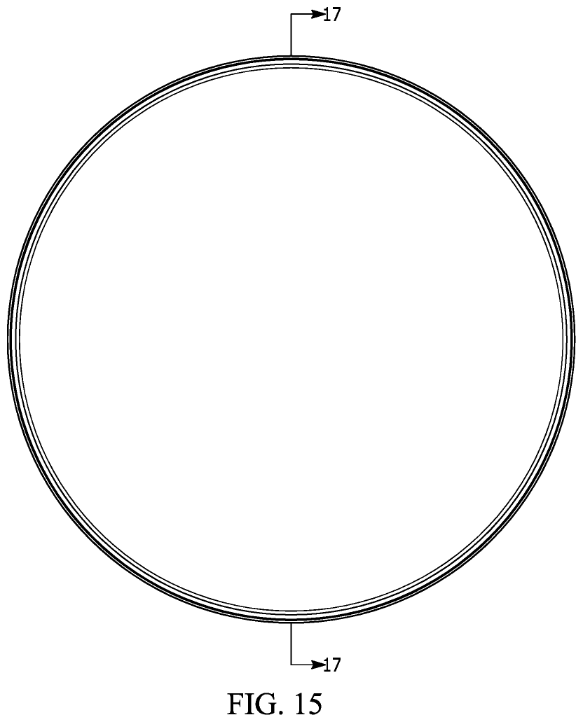

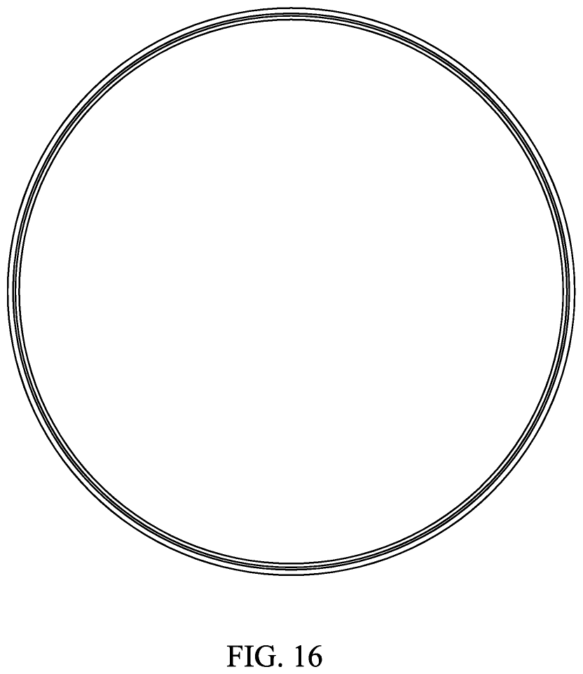

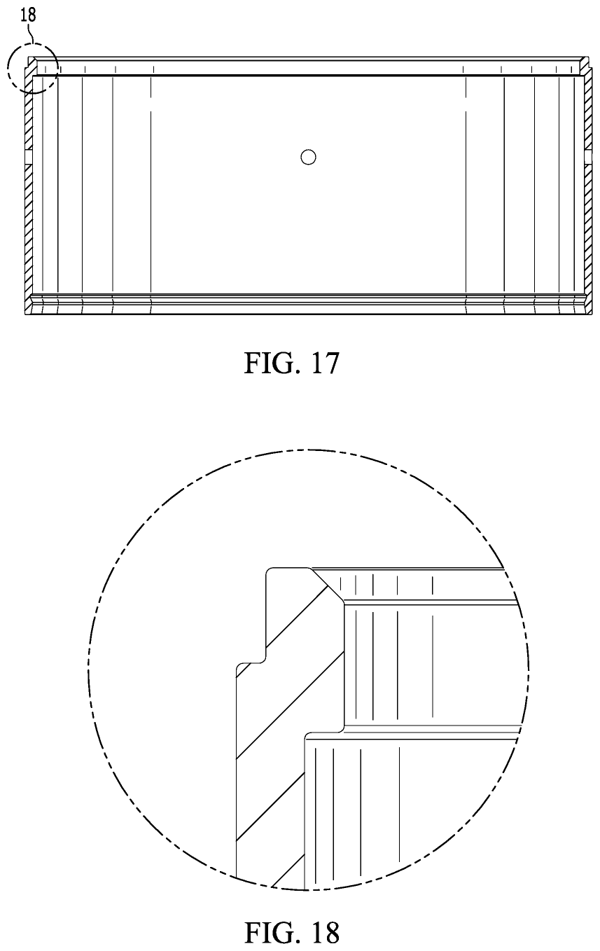

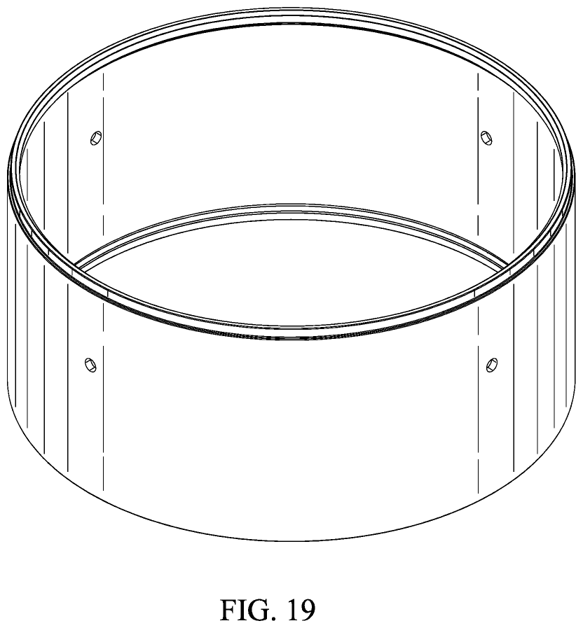

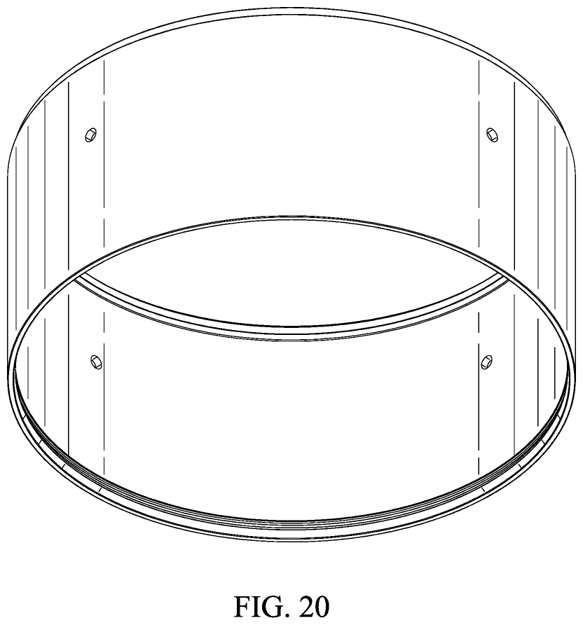

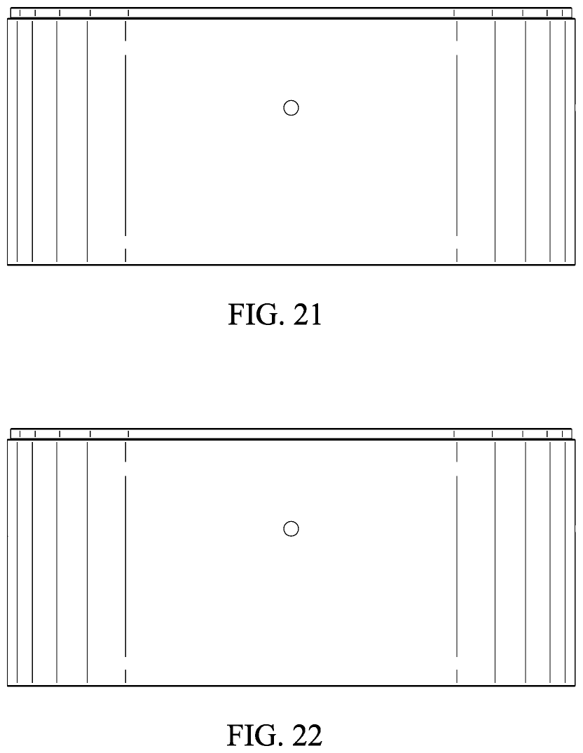

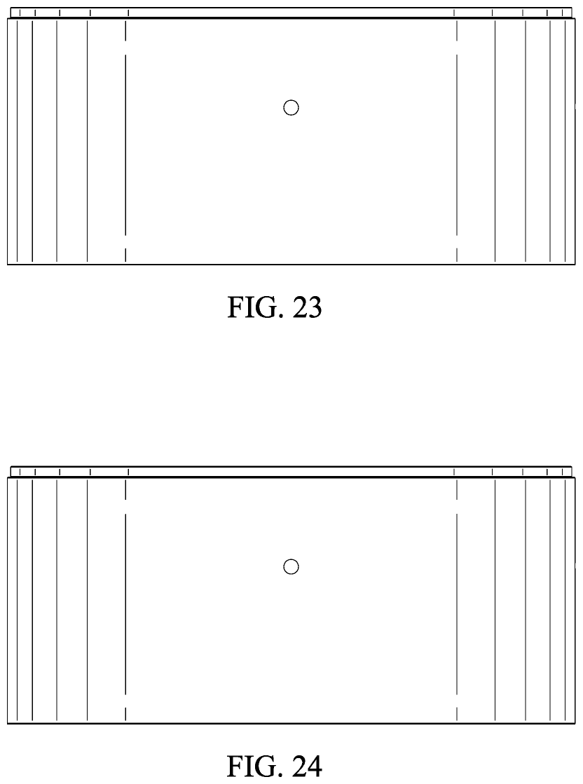

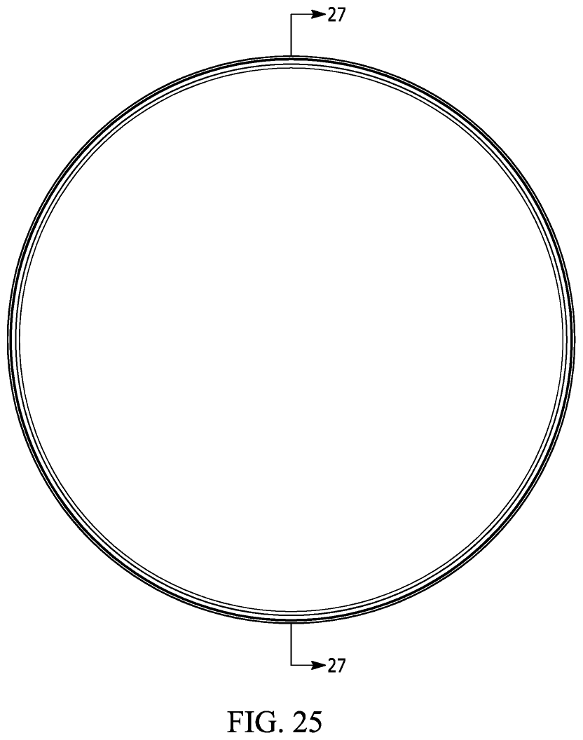

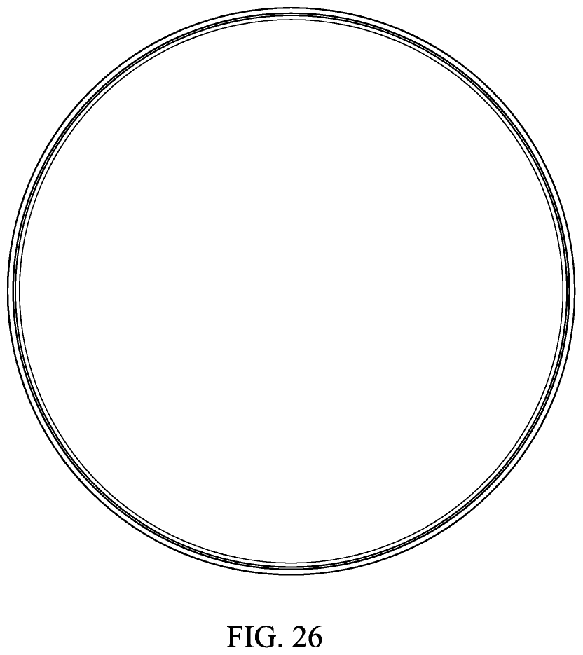

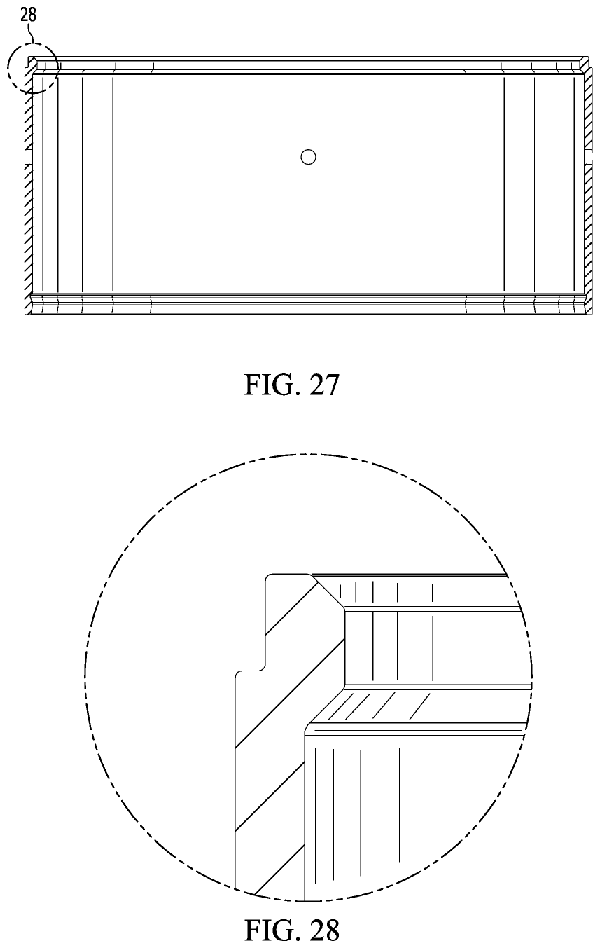

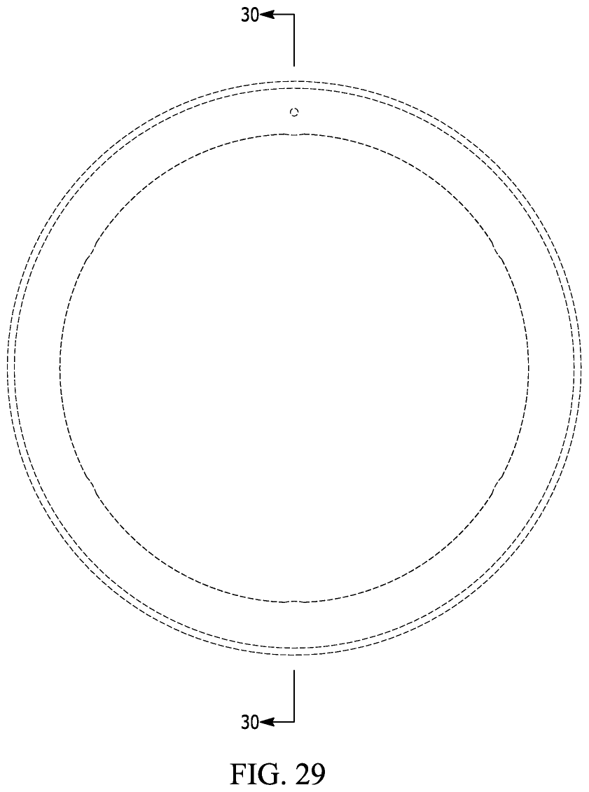

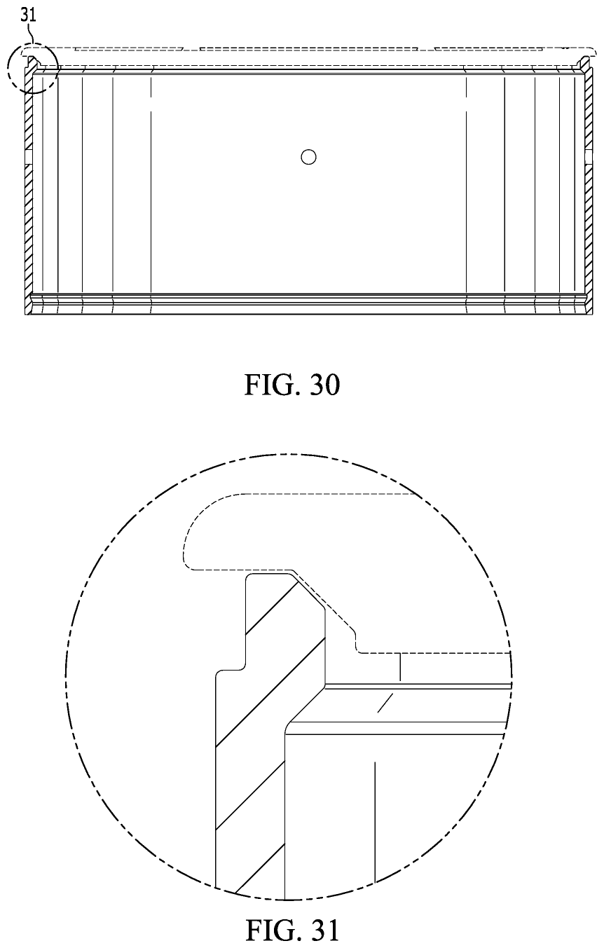

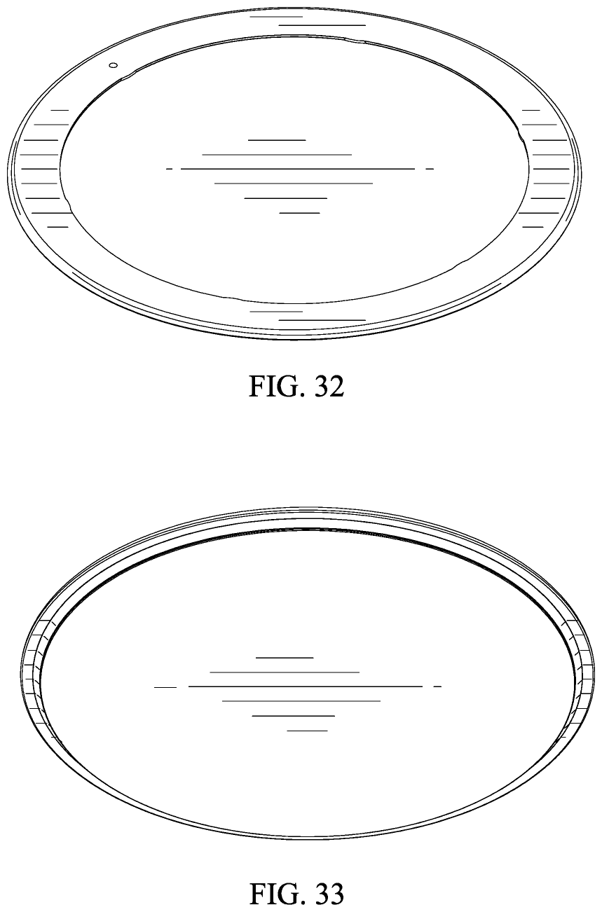

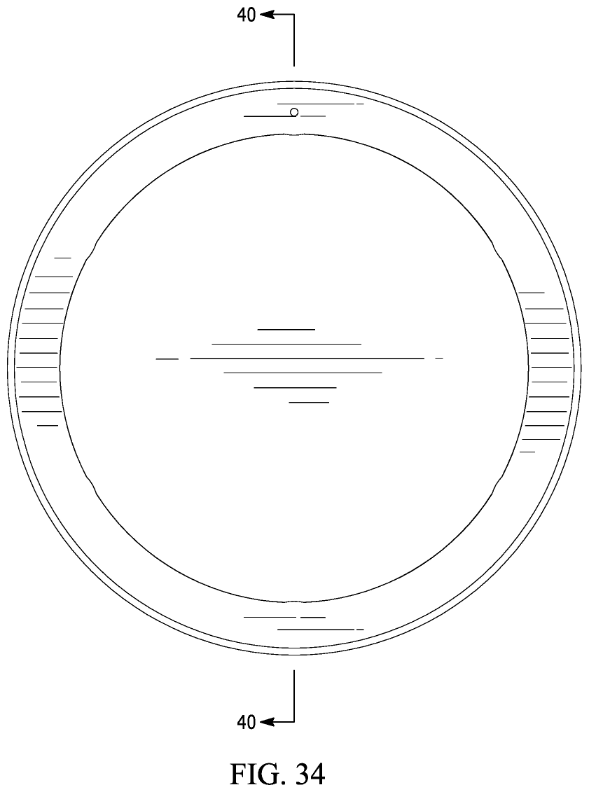

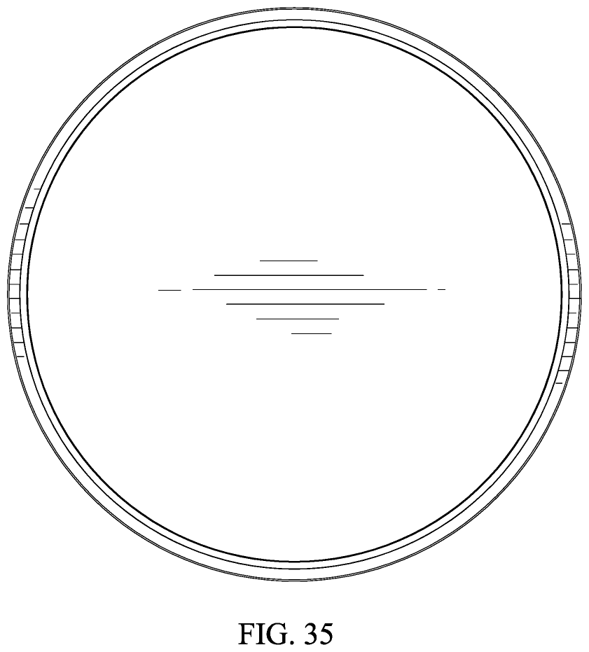

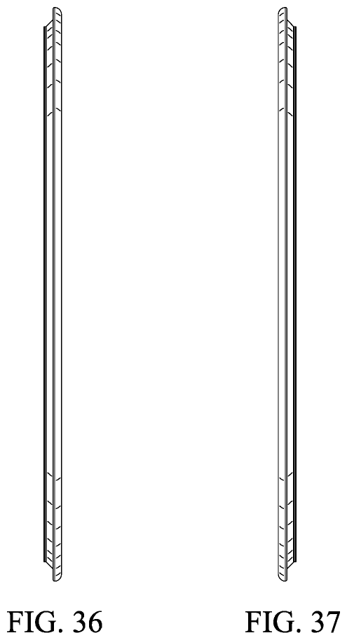

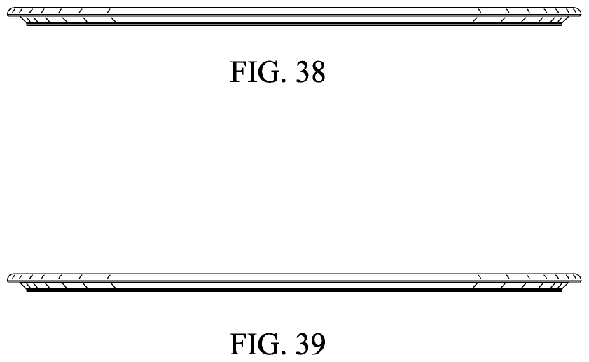

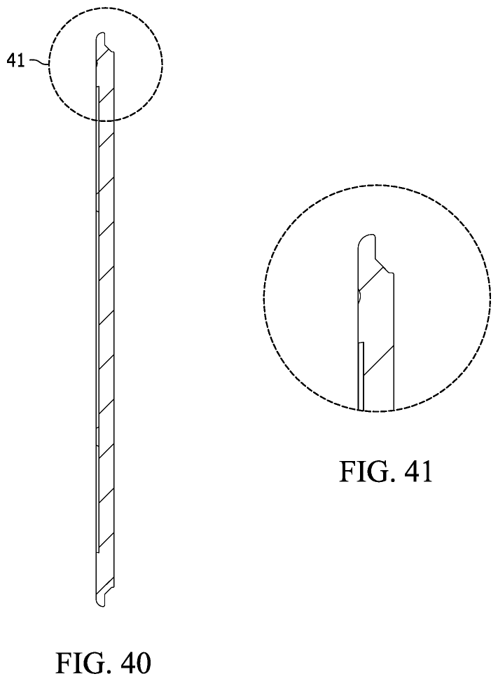

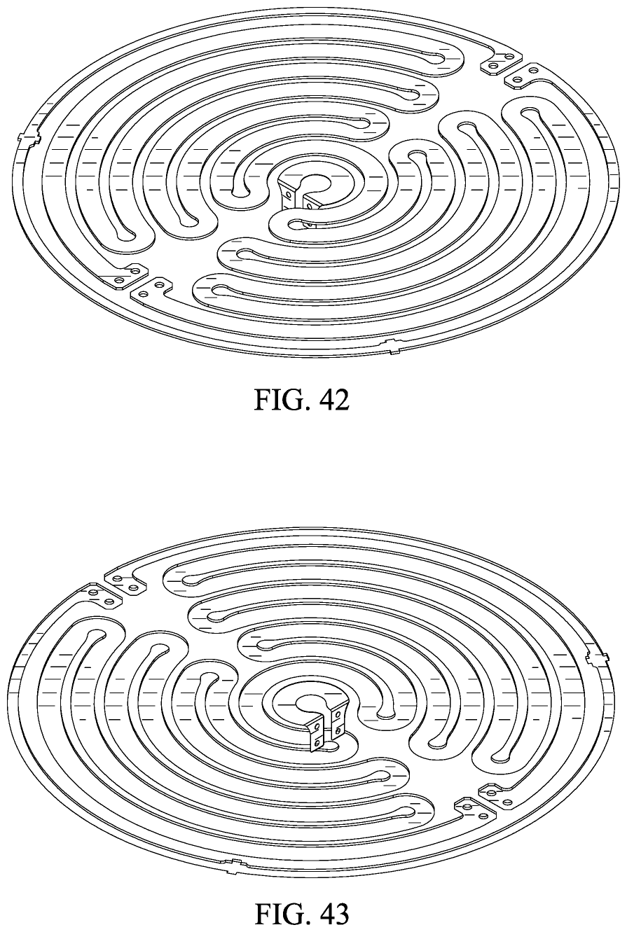

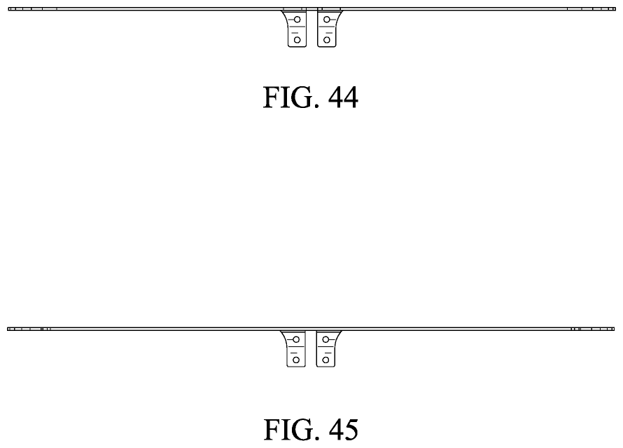

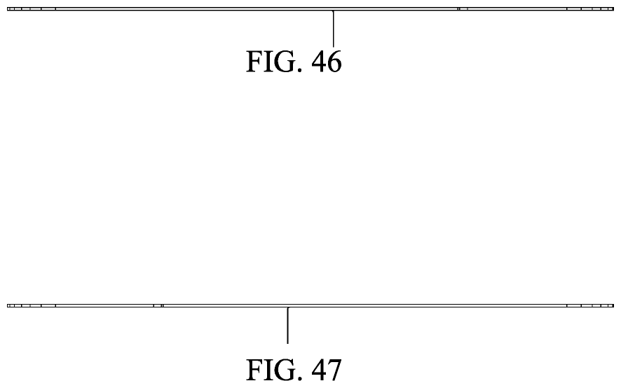

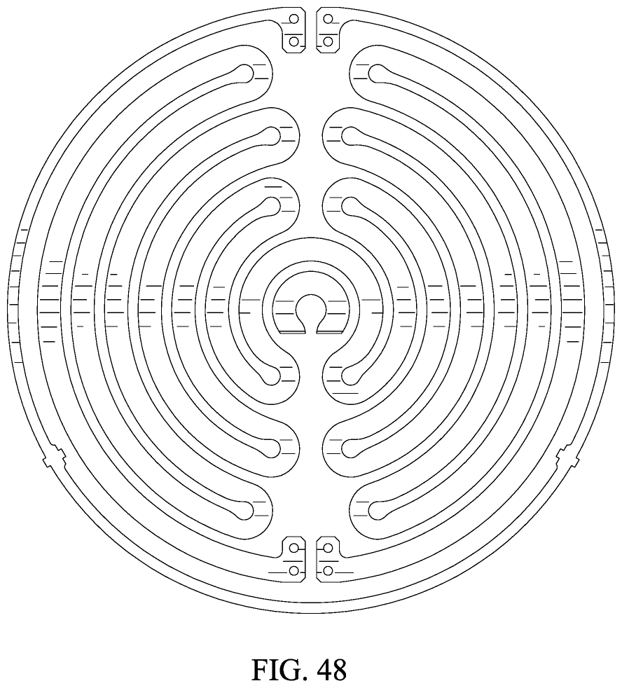

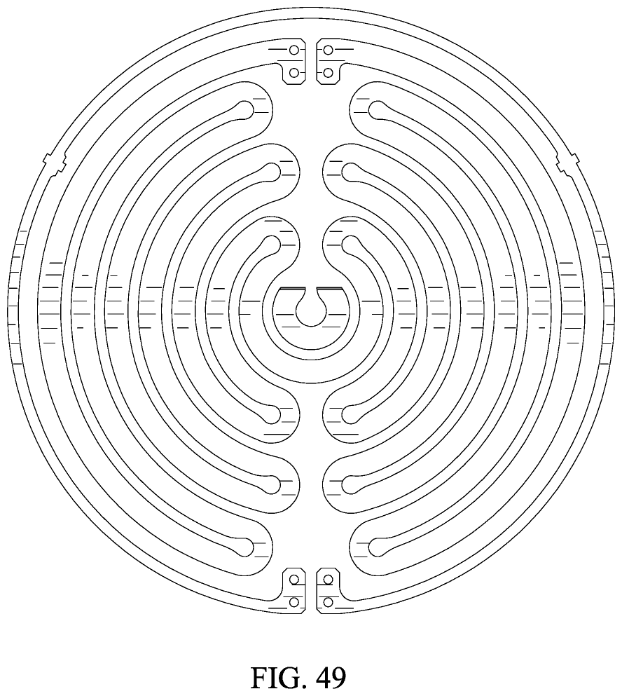

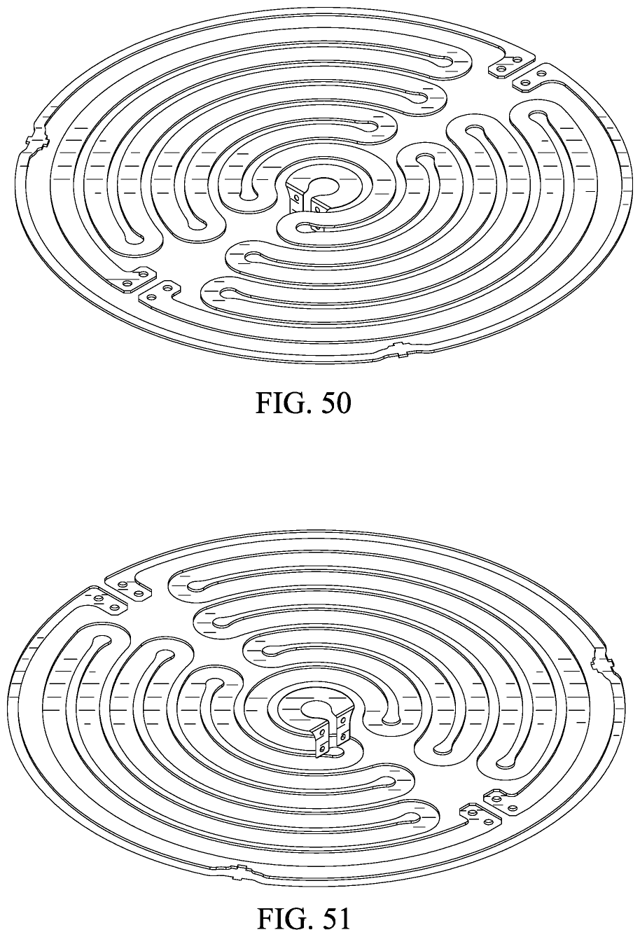

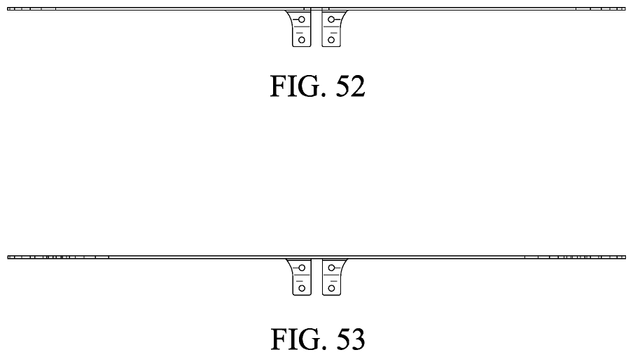

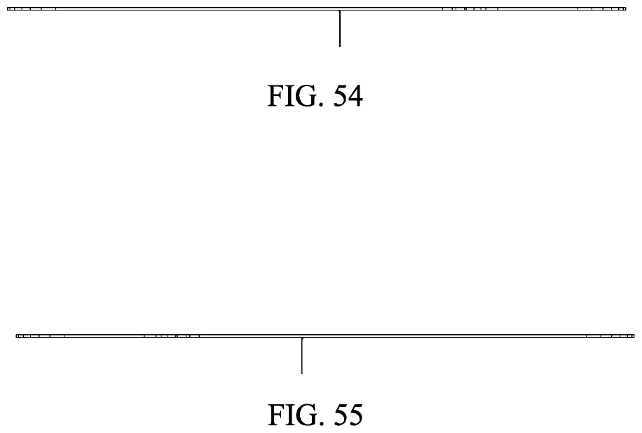

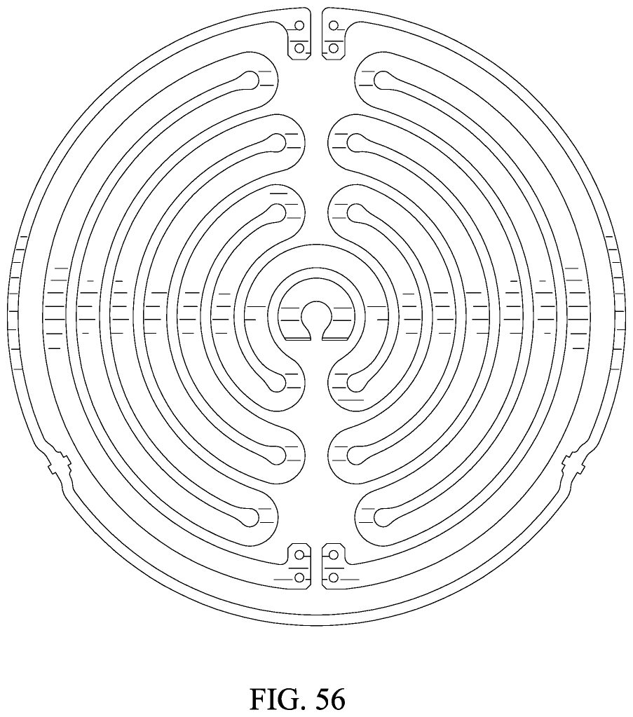

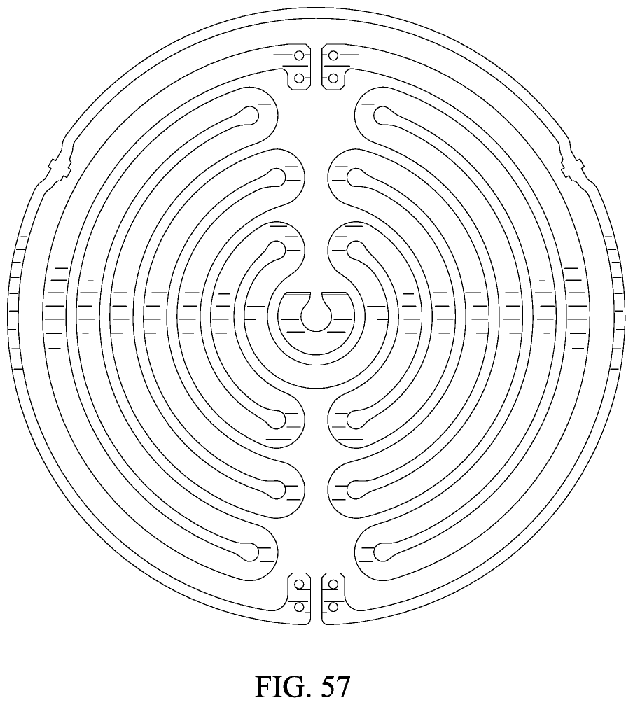

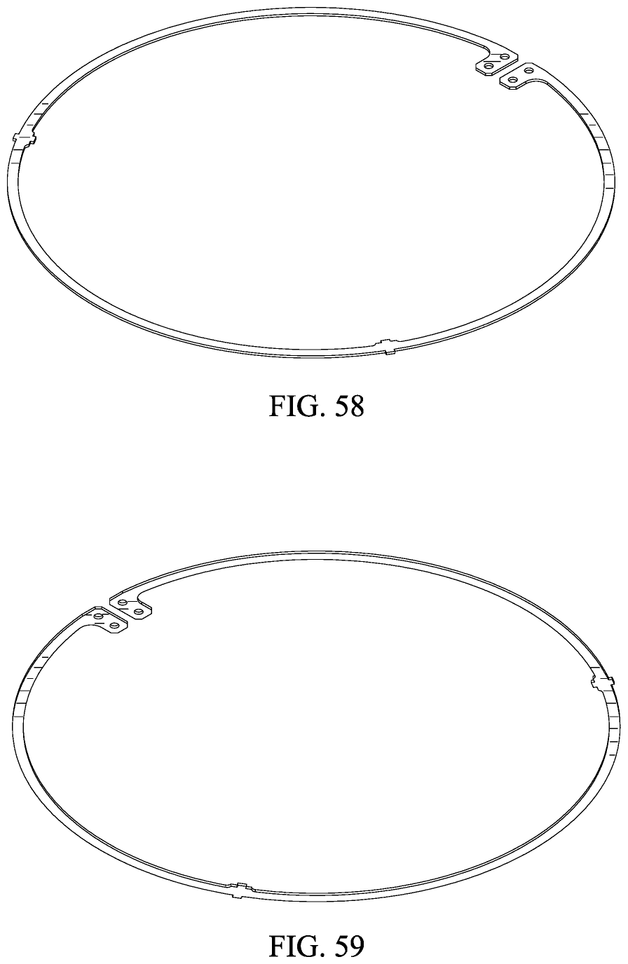

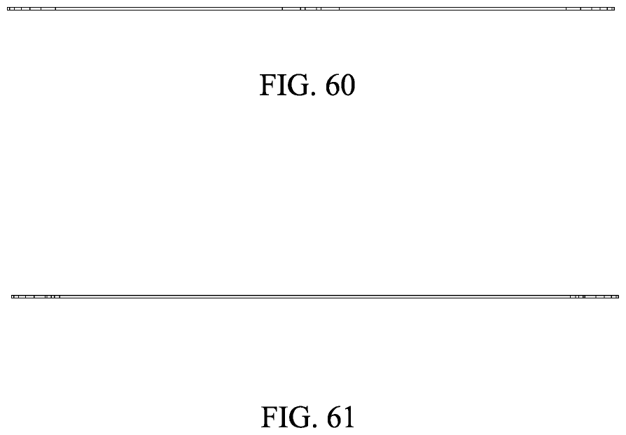

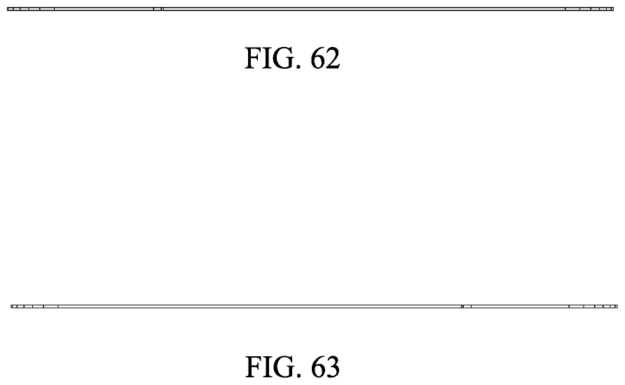

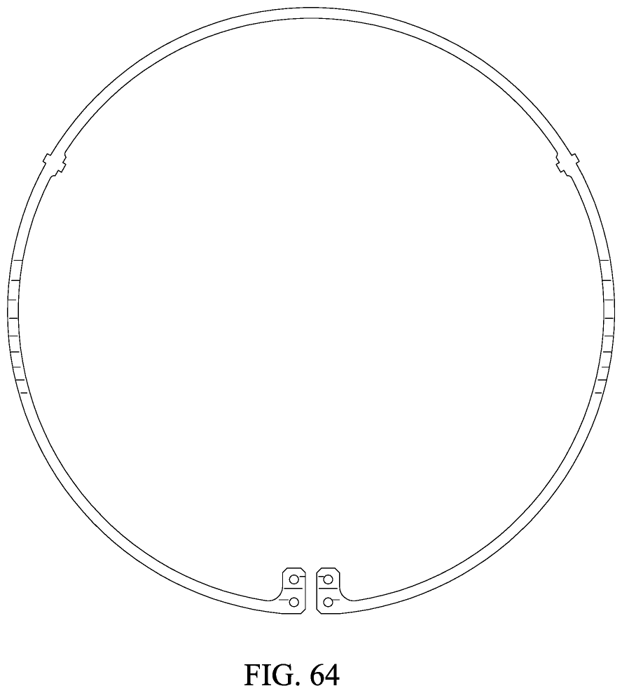

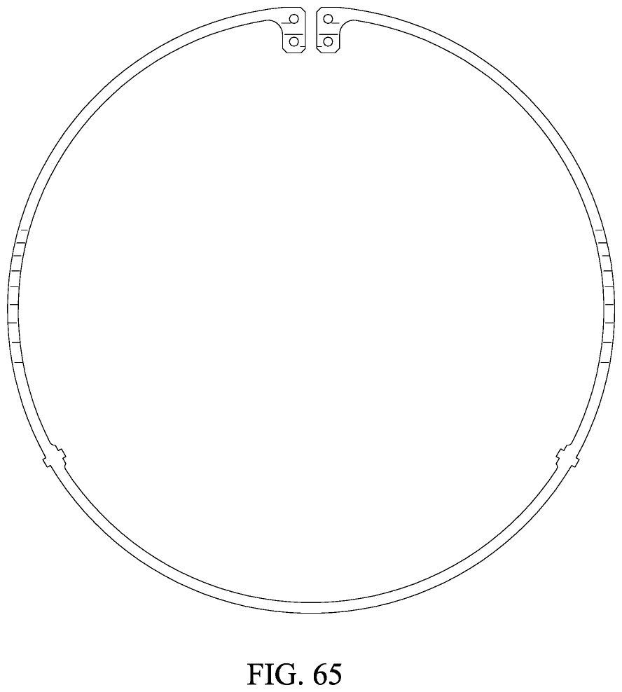

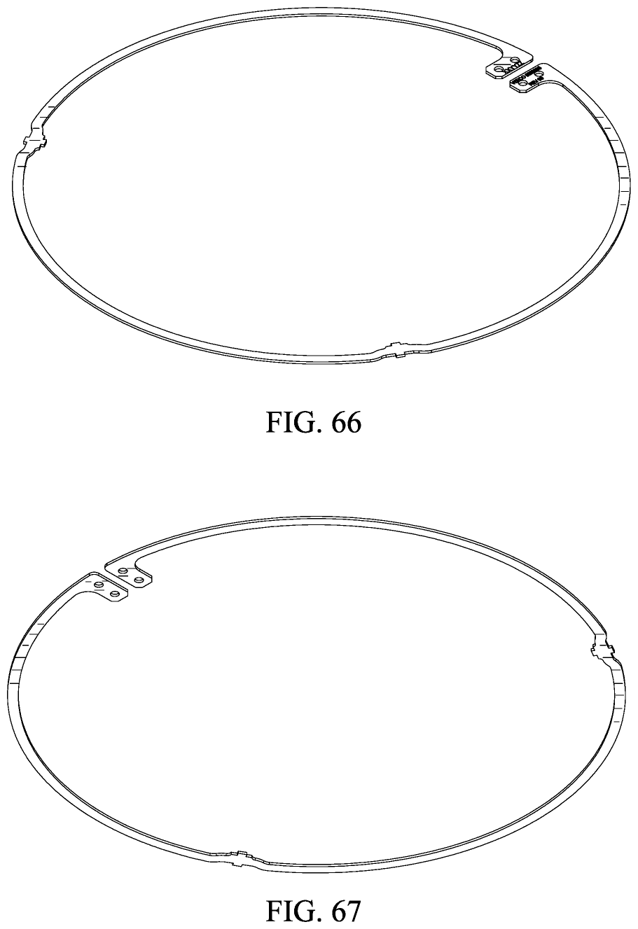

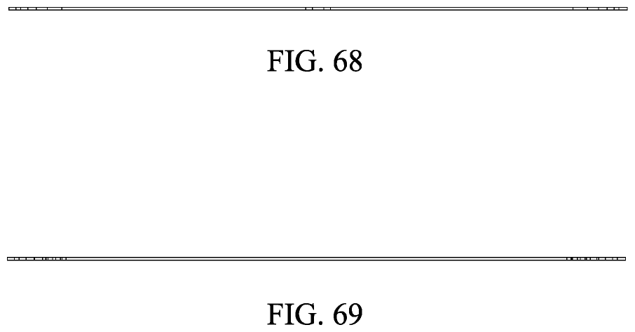

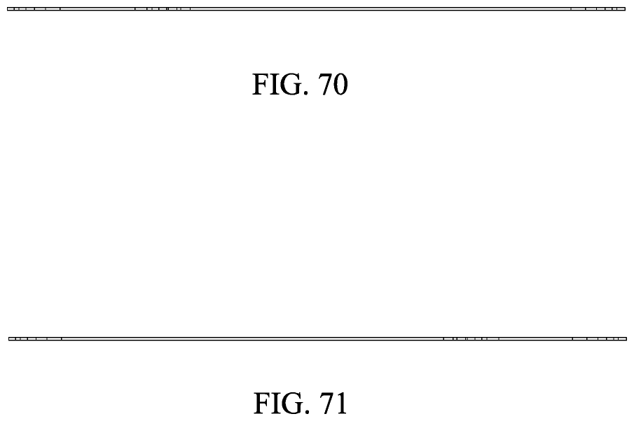

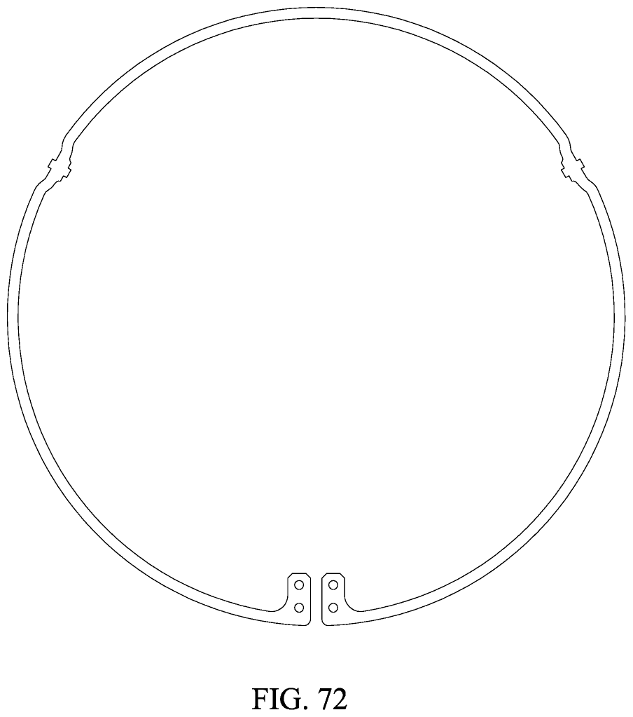

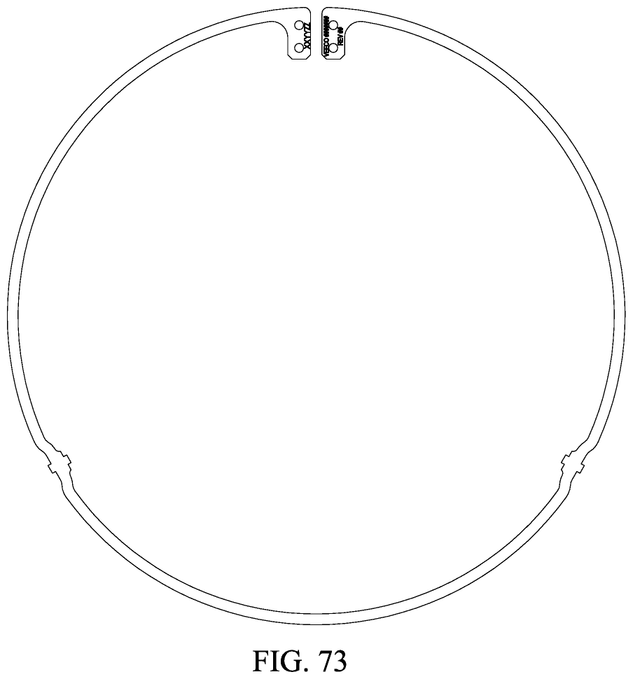

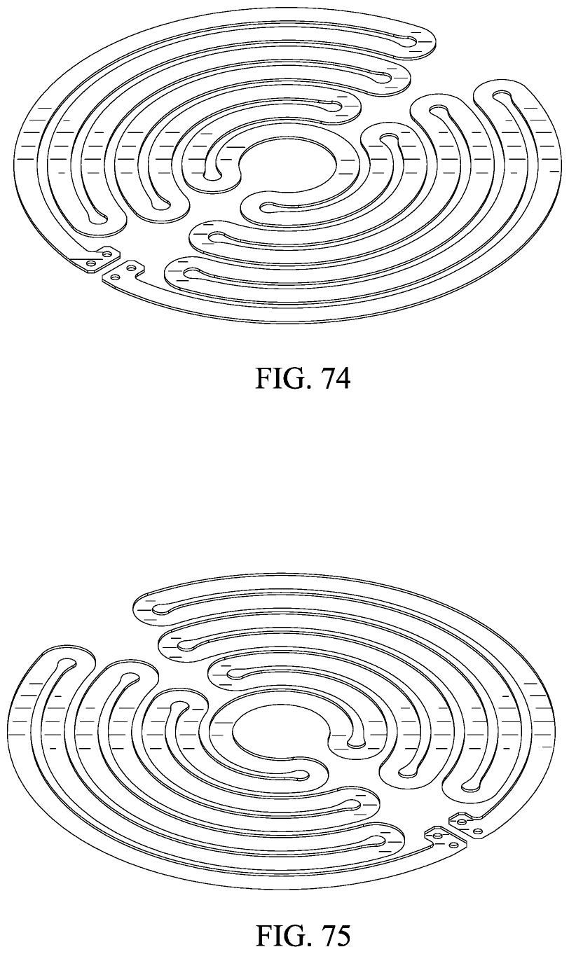

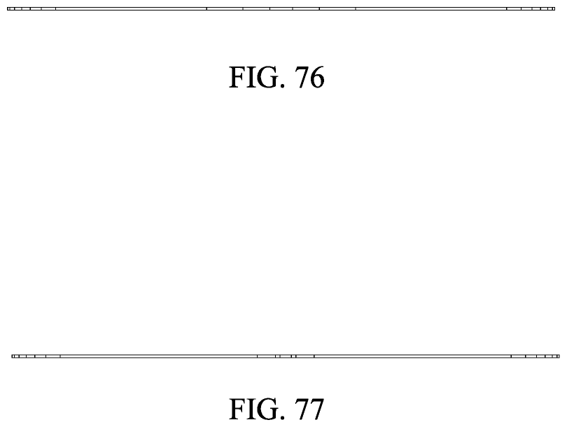

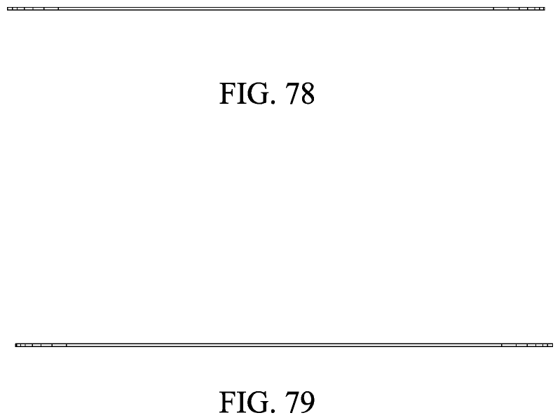

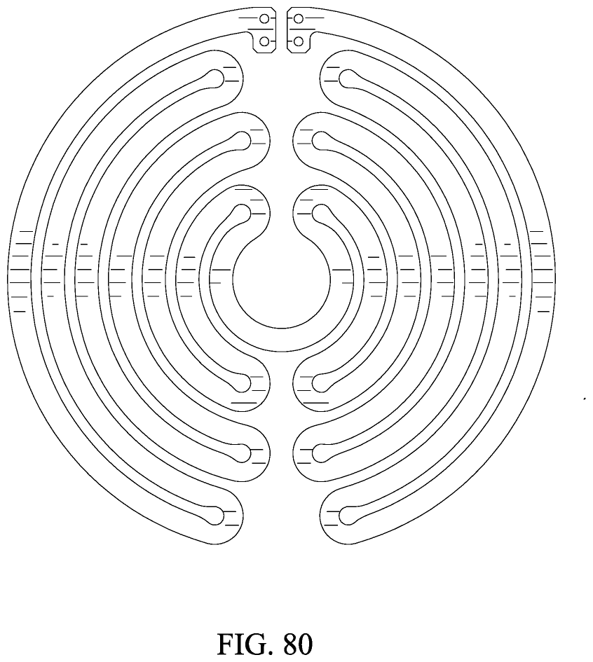

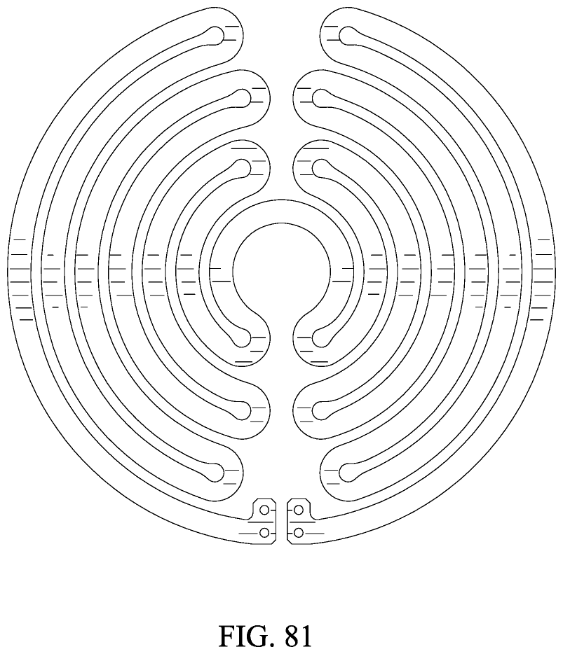

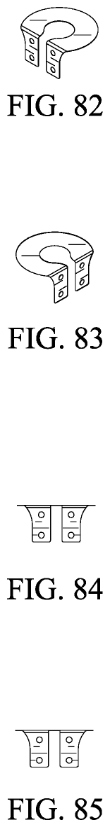

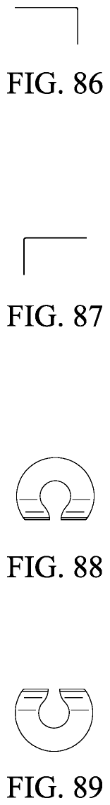

FIG. 8 illustrates a partial view of a CVD reactor system 800 that comprises an embodiment of a substrate carrier and rotating tube of the present teaching. The sidewall of the rotating tube 802 is shown with vent hole 804. The top region 806 of the rotating tube 802 illustrates the outer notch 808, beveled edge 810, and lower beveled lip 812. The substrate carrier 814 includes a beveled edge 816 that matches the beveled edge 810 of the rotating tube 802. There is a flat rim 818 that sits on the top of the rotating tube 802.

The single wafer CVD reactor of the present invention can also be connected to a modular CVD system which includes an equipment front end module (EFEM) or an automated front-end interface (AFI), the EFEM/AFI having aligner(s), robot(s), and other tools normally found in CVD or semi processing tools, one or more load locks, and a vacuum transfer module. There can be one to four single wafer CVD reactors operably connected to the vacuum transfer module. The single wafer CVD reactors can be operably coupled to one or more source delivery assemblies. Each source delivery assembly can include one or more reaction gases, cooling systems and ventilation systems. The EFEM/AFI is coupled to the one or more load locks. In turn, the one or more load locks are operably connected to the vacuum transfer module. Wafer cassettes and substrate carriers are loaded into suitable wafer or substrate cassettes or front opening unified pods (FOUP) and mounted on the EFEM/AFI. A robot within the EFEM/AFI then loads the wafers on the substrate carriers. The robot can then place the substrate carrier with loaded wafer onto a shelve within the load locks. A robot within the vacuum transfer module then takes the substrate carrier with wafer and places it into the single wafer CVD reactor(s) which are coupled to the vacuum transfer module. After the wafer(s) are processed, the substrate carrier with processed wafer are removed from the single wafer CVD reactor(s) by the vacuum transfer module robot and placed in the load locks. The robot within the EFEM/AFI then removes the substrate carrier with processed wafer from the load locks and places them within the EFEM/AFI. The EFEM/AFI robot then removes the processed wafer from the substrate carrier and places the processed wafer into FOUP for further processing.

One aspect of the present teaching is a method of manufacturing a self-centering substrate carrier system for a chemical vapor deposition (CVD) reactor that includes forming a rotating tube comprising a beveled surface and a rim and forming a substrate carrier that at least partially supports a wafer for CVD processing and that has a beveled surface and a rim. A cross section of the substrate carrier is formed in a shape and with dimensions that result in a center of mass of the substrate carrier being positioned a distance that is below a plane of contact defined by where the rim of substrate carrier contacts the rim of the rotating tube.

Some methods include forming the cross section of the substrate carrier in the shape and with the dimensions that result in the center of mass of the substrate carrier being positioned at the distance that is less than 1.0 mm from the plane of contact defined by where the rim of the substrate carrier contacts the rim of the rotating tube. Also, some methods include forming the cross section of the substrate carrier in the shape and with the dimensions that result in the center of mass of the substrate carrier being positioned at the distance that is less than 0.5 mm from the plane of contact defined by where the rim of substrate carrier contacts the rim of the rotating tube. Also, some method include forming the cross section of the substrate carrier in the shape and with the dimensions that result in the center of mass of the substrate carrier being positioned at a distance that is at the plane of contact defined by where the rim of substrate carrier contacts the rim of the rotating tube.

In addition, some methods include forming the cross section of the substrate carrier in the shape and with the dimensions that result in the center of mass of the substrate carrier being positioned at the distance that is above the plane of contact defined by where the rim of substrate carrier contacts the rim of the rotating tube. Also, some method include forming the cross section of the substrate carrier in the shape and with the dimensions that result in the center of mass of the substrate carrier being positioned at the distance that is below the plane of contact defined by where the rim of substrate carrier contacts the rim of the rotating tube.

Furthermore, some methods include forming the cross section of the substrate carrier in the shape and with the dimensions that minimize a destabilizing moment produced during rotation. Also, some methods include forming the cross section of the substrate carrier in a shape and with dimensions so that there is a coincident alignment of a central axis of the substrate carrier and a rotation axis of the rotating tube during processing at a desired process temperature. Also, some methods include forming the substrate carrier so the substrate carrier supports an entire bottom surface of the wafer. Also some methods include forming the substrate carrier so the substrate carrier supports the wafer at a perimeter of the wafer, leaving a portion of both a top and a bottom surface of the wafer exposed. Also, some methods include forming the substrate carrier in a shape and with dimensions so that a rotation eccentricity of the wafer is substantially zero at the desired process temperature. Also, some methods include forming the substrate carrier and rotating tube so that the beveled surface of the substrate carrier and the beveled surface of the rotating tube define a gap. The width of the gap in some methods approaches zero at the desired process temperature.

Yet other methods include determining a coefficient of friction between the substrate carrier and the rotation tube and then forming the bevel surface of the substrate carrier and the beveled surface of the rotating tube at angle α relative to a rotation axis such that tan(α)>ƒ, where ƒ is the coefficient of friction between the substrate carrier and rotation tube. Yet other methods include forming at least one vent in the sidewalls of the rotating tube.

### Equivalents

While the Applicant's teaching is described in conjunction with various embodiments, it is not intended that the Applicant's teaching be limited to such embodiments. On the contrary, the Applicant's teaching encompass various alternatives, modifications, and equivalents, as will be appreciated by those of skill in the art, which may be made therein without departing from the spirit and scope of the teaching.

What is claimed is:

1. A self-centering substrate carrier system for a chemical vapor deposition (CVD) reactor, the substrate carrier system comprising:
a) a substrate carrier comprising a beveled surface, the substrate carrier being configured to at least partially support a wafer for CVD processing; and
b) a rotating tube comprising a beveled surface that matches the beveled surface of the substrate carrier, a shape and dimensions of a cross section of the substrate carrier being chosen such that a center of mass of the substrate carrier is positioned below a plane of contact defined by where a rim of substrate carrier contacts a rim of the rotating tube.

2. The self-centering substrate carrier system of claim 1 wherein the shape and dimensions of the cross section of the substrate carrier are chosen such that the center of mass of the substrate carrier is positioned such that the distance is less than 1.0 mm from the plane of contact between the substrate carrier and rotating tube.

3. The self-centering substrate carrier system of claim 1 wherein the shape and dimensions of the cross section of the substrate carrier are chosen such that the center of mass of the substrate carrier is positioned such that the distance is less than 0.5 mm from the plane of contact between the substrate carrier and rotating tube.

4. The self-centering substrate carrier system of claim 1 wherein the shape and dimensions of the cross section of the substrate carrier are chosen such that the center of mass of the substrate carrier is positioned at the plane of contact between the substrate carrier and rotating tube.

5. The self-centering substrate carrier system of claim 1 wherein the shape and dimensions of the cross section of the substrate carrier is chosen to minimize a destabilizing moment produced during rotation.

6. The self-centering substrate carrier system of claim 1 wherein the shape and dimensions of the substrate carrier are chosen so that there is a coincident alignment of a central axis of the substrate carrier and a rotation axis of the rotating tube during processing at a desired process temperature

7. The self-centering substrate carrier system of claim 6 wherein the coincident alignment of the central axis of the substrate carrier and the rotation axis of the rotating tube during processing at the desired process temperature establishes an axial-symmetrical temperature profile across the wafer.

8. The self-centering substrate carrier system of claim 1 wherein the substrate carrier supports an entire bottom surface of the wafer.

9. The self-centering substrate carrier system of claim 1 wherein the substrate carrier supports the wafer at a perimeter of the wafer, leaving a portion of both a top and a bottom surface of the wafer exposed.

10. The self-centering substrate carrier system of claim 1 wherein a shape and dimensions of the substrate carrier are chosen so that a rotation eccentricity of the wafer is substantially zero at the desired process temperature.

11. The self-centering substrate carrier system of claim 1 wherein the beveled surface of the substrate carrier and the beveled surface of the rotating tube are dimensioned to define a gap.

12. The self-centering substrate carrier system of claim 11 wherein a width of the gap approaches zero at the desired process temperature.

13. The self-centering substrate carrier system of claim 11 wherein a coefficient of thermal expansion of a material forming the substrate carrier and a coefficient of thermal expansion of a material forming the rotating tube are chosen so that a width of the gap reduces during heating due to thermal expansion.

14. The self-centering substrate carrier system of claim 11 wherein a coefficient of thermal expansion of a material forming the substrate carrier and a coefficient of thermal expansion of a material forming the rotating tube are chosen so that the gap is maintained at processing temperatures.

15. The self-centering substrate carrier system of claim 11 wherein a width of the gap at room temperature is chosen so that there is space for expansion of the substrate carrier relative to the rotating tube at processing temperatures.

16. The self-centering substrate carrier system of claim 1 wherein the bevel surface of the substrate carrier and the beveled surface of the rotating tube are parallel to each other.

17. The self-centering substrate carrier system of claim 1 wherein the bevel surface of the substrate carrier and the beveled surface of the rotating tube are each at angle α relative to a rotation axis such that tan(α)>ƒ, where ƒ is a coefficient of friction between the substrate carrier and rotation tube.

18. The self-centering substrate carrier system of claim 1 wherein the cross section of the substrate carrier is formed in a substantially rectangular shape overall.

19. The self-centering substrate carrier system of claim 1 wherein the rotating tube comprises vented sidewalls.

20. The self-centering substrate carrier system of claim 1 wherein the vented sidewalls are configured to equalize pressure in the regions above and below the substrate carrier.

21. A method of manufacturing a self-centering substrate carrier system for a chemical vapor deposition (CVD) reactor, the method comprising:
a) forming a rotating tube comprising a beveled surface and a rim; and
b) forming a substrate carrier that at least partially supports a wafer for CVD processing and that has a beveled surface and a rim, a cross section of the substrate carrier being formed in a shape and with dimensions that result in a center of mass of the substrate carrier being positioned a distance that is below a plane of contact defined by where the rim of substrate carrier contacts the rim of the rotating tube.
